(19) United States
(12) Patent Application Publication
(10) Pub. No.: US 2026/0030858 A1
(43) Pub. Date: Jan. 29, 2026

(54) SUBTRACTIVE DEFECT LOCALIZATION FOR CHARGED-PARTICLE MICROSCOPY

(71) Applicant: FEI Company, Hillsboro, OR (US)

(72) Inventor: Lucas Winiarski, Portland, OR (US)

(21) Appl. No.: 18/781,525

(22) Filed: Jul. 23, 2024

(51) Int. Cl. G06V 10/25; G06T 7/00; G06V 10/26; G06V 10/82

(52) U.S. Cl. CPC G06V 10/25; G06T 7/001; G06V 10/26; G06V 10/82; G06T 2207/10061; G06T 2207/20084; G06T 2207/20224; G06T 2207/30148

(57) ABSTRACT

Systems/techniques are provided for facilitating subtractive defect localization for charged-particle microscopy. In various embodiments, a system can access an image captured by a charged-particle microscope, wherein the image depicts a specimen. In various aspects, the system can localize one or more defective instantiations of a structure of interest of the specimen, based on execution of a first machine learning model that is trained to localize non-defective versions of the structure of interest.

### BACKGROUND

When given an image captured by a charged-particle microscope, localizing defective structures of interest in that image can be difficult.

### SUMMARY

The following presents a summary to provide a basic understanding of one or more embodiments. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus or computer program products that facilitate subtractive defect localization for charged-particle microscopy are described.

According to one or more embodiments, a system is provided. The system can comprise a non-transitory computer-readable memory that can store computer-executable components. The system can further comprise a processor that can be operably coupled to the non-transitory computer-readable memory and that can execute the computer-executable components stored in the non-transitory computer-readable memory. In various embodiments, the computer-executable components can comprise an access component that can access an image captured by a charged-particle microscope, wherein the image depicts a specimen. In various aspects, the computer-executable components can comprise a subtraction component that can localize one or more defective instantiations of a structure of interest of the specimen, based on execution of a first machine learning model that is trained to localize non-defective versions of the structure of interest.

According to one or more embodiments, a computer-implemented method is provided. In various embodiments, the computer-implemented method can comprise accessing, by a device operatively coupled to a processor, an image captured by a charged-particle microscope, wherein the image depicts a specimen. In various aspects, the computer-implemented method can comprise localizing, by the device, one or more defective instantiations of a structure of interest of the specimen, based on executing on the image a first machine learning model that is trained to localize non-defective versions of the structure of interest.

According to one or more embodiments, a computer program product for facilitating subtractive defect localization for charged-particle microscopy is provided. In various embodiments, the computer program product can comprise a non-transitory computer-readable memory having program instructions embodied therewith. In various aspects, the program instructions can be executable by a processor to cause the processor to access a scanned image depicting a semiconductor device having a repeated structure of interest. In various instances, the program instructions can be executable to cause the processor to execute a defect-selective localizer on the scanned image, thereby yielding a set of first localizations that respectively indicate where in the scanned image non-defective instantiations of the repeated structure of interest are located. In various cases, the program instructions can be executable to cause the processor to execute a defect-agnostic localizer on the scanned image, thereby yielding a set of second localizations that respectively indicate where in the scanned image defective or non-defective instantiations of the repeated structure of interest are located. In various aspects, the program instructions can be executable to cause the processor to subtract the set of first localizations from the set of second localizations, thereby yielding a set of third localizations that respectively indicate where in the scanned image defective instantiations of the repeated structure of interest are located.

### DESCRIPTION OF THE DRAWINGS

Various embodiments will be readily understood by the following detailed description in conjunction with the accompanying figures. To facilitate this description, like reference numerals designate like structural elements. Embodiments are illustrated by way of example, not by way of limitation, in the figures. The figures are not necessarily drawn to scale.

FIG. 1 illustrates an example, non-limiting block diagram of a scientific instrument module in accordance with various embodiments described herein.

FIG. 2 illustrates an example, non-limiting flow diagram of a computer-implemented method in accordance with various embodiments described herein.

FIG. 3 illustrates a block diagram of an example, non-limiting system that facilitates subtractive defect localization for charged-particle microscopy in accordance with one or more embodiments described herein.

FIG. 4 illustrates a block diagram of an example, non-limiting system including a first machine learning model and a set of non-defective localizations that facilitates subtractive defect localization for charged-particle microscopy in accordance with one or more embodiments described herein.

FIG. 5 illustrates an example, non-limiting block diagram showing how a first machine learning model can produce a set of non-defective localizations in accordance with one or more embodiments described herein.

FIG. 6 illustrates a block diagram of an example, non-limiting system including a set of defect-agnostic localizations that facilitates subtractive defect localization for charged-particle microscopy in accordance with one or more embodiments described herein.

FIGS. 7-9 illustrate example, non-limiting block diagrams showing how a set of defect-agnostic localizations can be obtained in accordance with one or more embodiments described herein.

FIG. 10 illustrates a block diagram of an example, non-limiting system including a set of defective localizations that facilitates subtractive defect localization for charged-particle microscopy in accordance with one or more embodiments described herein.

FIG. 11 illustrates an example, non-limiting block diagram showing how a set of defective localizations can be obtained based on a set of non-defective localizations and a set of defect-agnostic localizations in accordance with one or more embodiments described herein.

FIGS. 12-15 illustrate example, non-limiting experimental results in accordance with one or more embodiments described herein.

FIG. 16 illustrates an example, non-limiting block diagram showing how various artificial intelligence models can be trained in accordance with one or more embodiments described herein.

FIG. 17 illustrates an example, non-limiting block diagram of a graphical user interface that can be used in the performance of some or all of the methods or techniques disclosed herein, in accordance with various embodiments described herein.

FIG. 18 illustrates an example, non-limiting block diagram of a computing device that can perform some or all of the methods or techniques disclosed herein, in accordance with various embodiments described herein.

FIG. 19 illustrates an example, non-limiting block diagram of a scientific instrument support system in which some or all of the methods or techniques disclosed herein may be performed, in accordance with various embodiments described herein.

FIG. 20 illustrates a block diagram of an example, non-limiting operating environment in which one or more embodiments described herein can be facilitated.

FIG. 21 illustrates an example networking environment operable to execute various implementations described herein.

FIG. 22 illustrates an example dual beam microscope that can be implemented in accordance with various embodiments described herein.

### DETAILED DESCRIPTION

The following detailed description is merely illustrative and is not intended to limit embodiments or application/uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiments. Various additional operations can be performed, or described operations can be omitted in additional embodiments.

Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices. As used herein, the phrase “based on” should be understood to mean “based at least in part on,” unless otherwise specified.

A charged-particle microscope (e.g., a scanning electron microscope (SEM), a transmission electron microscope (TEM), a dual beam microscope) can be any suitable computerized device that can capture or generate microscopic or nanoscopic images of specimens in a scientific, laboratory, research, or clinical operational environment. To facilitate the capture or generation of such images, charged-particle microscopes can leverage complex arrangements of actuatable parts (e.g., ion sources, electron sources, optical lenses or apertures, optical plates or deflectors, columns, coils, heaters, coolers, fluid valves, fluid pumps, circuit switches, specimen stages), sensors (e.g., ion detectors, electron detectors, voltmeters, thermistors, potentiometers, pressure gauges), or consumables (e.g., carrier fluids, calibrants, filters, reactive gases).

A specimen (e.g., an integrated circuit chip, a semiconductor wafer, a lamella) can be fabricated or manufactured via any suitable photolithographic techniques (e.g., etching, deposition) so as to have or otherwise contain any suitable structure of interest (e.g., fin, gate, drain, nanowire), where the structure of interest is repeated or duplicated multiple times on or in the specimen. In other words, the specimen can have or contain multiple instantiations, versions, or copies of the structure of interest. Ideally, it can be desired for all those instantiations, versions, or copies of the structure of interest to be non-damaged or otherwise non-defective (e.g., to be physically constructed in compliance with applicable structural, design, or engineering tolerances). However, in reality, various of those instantiations, versions, or copies of the structure of interest can instead be damaged or defective (e.g., can exhibit physical or structural anomalies due to wear and tear from use or due to malformation during fabrication or manufacturing).

Accordingly, an image of the specimen can be captured by a charged-particle microscope, and it can be desired to localize, via machine learning and within that image, any damaged or defective instantiations, versions, or copies of the structure of interest. Upon being localized, those damaged or defective instantiations, versions, or copies of the structure of interest can be repaired or otherwise addressed in any suitable fashion, or whatever machinery was used to fabricate or manufacture the specimen can be inspected, repaired, or otherwise addressed in any suitable fashion.

As the inventors of various embodiments described herein recognized, such damage/defect localization can be considered as a difficult or non-trivial machine learning task.

Indeed, existing techniques facilitate such task by training, in supervised fashion, a machine learning model to selectively localize damaged or defective versions of the structure of interest. Such supervised training relies upon training images that are annotated with respective ground-truth localizations that show or otherwise indicate where in those training images damaged or defective versions of the structure of interest are known to be located. In other words, such supervised training can be considered as teaching the machine learning model how to visually recognize a damaged or defective version of the structure of interest.

Unfortunately, as the present inventors realized, the machine learning model of existing techniques can learn to recognize only damaged or defective versions of the structure of interest that are visually similar to those that are present in the training dataset. In the real-world, there are effectively an infinite number of different or unique ways for an instantiation, version, or copy of the structure of interest to physically manifest damage or defectiveness (e.g., there are effectively an infinite number of ways that different portions of the structure of interest can be deformed, warped, bent, or broken by different extents in different directions). In contrast, there can only be a finite number of training images, and thus only a finite number of damage or defect representations, in the training dataset. In other words, damage or defects in the structure of interest can exhibit nearly infinite structural diversity or variability, but it is not possible for the training dataset to span, capture, or otherwise represent such nearly infinite structural diversity or variability. So, when existing techniques are implemented, there will always be some types of damage or defects to the structure of interest that the machine learning model is not able to reliably recognize. For this reason, existing techniques can be considered as exhibiting lowered, reduced, or otherwise stunted damage/defect localization accuracy. Thus, existing techniques can be considered as disadvantageous.

Accordingly, systems or techniques that can improve the accuracy or reliability of damage/defect localization for images captured by charged-particle microscopes can be desirable.

Various embodiments described herein can address this technical problem. One or more embodiments described herein can include systems, computer-implemented methods, apparatus, or computer program products that can facilitate subtractive defect localization for charged-particle microscopy. In particular, the present inventors realized that, although there might be an infinite amount of structural diversity or variability in how the structure of interest can be damaged or defective, there can instead be a finite (e.g., indeed, a quite small) amount of structural diversity or variability in how the structure of interest can be undamaged or non-defective. In other words, there can be nearly infinitely many ways in which the structure of interest can look or appear disfigured (e.g., can look or appear not as intended or designed), but there can instead be only a few ways in which the structure of interest can look or appear not disfigured (e.g., can look or appear as intended or designed). In still other words, the structure of interest can be considered as having a nearly unconstrained state-space of possible defective states, but the structure of interest can be considered as instead having a tightly constrained state-space of possible non-defective states. The present inventors devised the herein-described techniques, so as to leverage this realization to improve defect localization.

Specifically, various embodiments described herein can involve training a first machine learning model to localize only non-defective versions of the structure of interest, rather than to localize only defective versions of the structure of interest. The first machine learning model can achieve high localization accuracy or reliability, due to the above-mentioned constrained non-defective state-space. After having been trained, the first machine learning model can be executed on any given image of the specimen, thereby yielding first localizations that indicate where within that given image non-defective versions of the structure of interest are located.

Furthermore, various embodiments described herein can include obtaining second localizations that indicate where within that given image all versions (e.g., both defective and non-defective) of the structure of interest are located. In some cases, the second localizations can be obtained by a second machine learning model that is trained to localize the structure of interest regardless of defect status (e.g., the second machine learning model can achieve high localization accuracy or reliability, since even never-before-seen defective versions of the structure of interest can nevertheless be easily recognizable as being the structure of interest). In other cases, the second localizations can be read from an electronic design file associated with the specimen (e.g., read from a computer-aided design (CAD) file that was used to fabricate or manufacture the specimen). In yet other cases, an example image can be obtained (e.g., from a CAD file) that shows how the specimen is ideally supposed, intended, or designed to look from the perspective of the given image, and the second localizations can be obtained by executing the first machine learning model on the example image (e.g., although the first machine learning model can localize only non-defective versions of the structure of interest, all versions of the structure of interest in the example image can be non-defective, thereby allowing the first machine learning model to localize all versions of the structure of interest in the example image).

Further still, various embodiments described herein can involve subtracting (e.g., via set subtraction) the first localizations from the second localizations. In various aspects, the resultant set obtained via such subtraction can be considered as localizations that show where in the given image defective versions of the structure of interest are located. In other words, by removing the set of localized non-defective structures of interest from the set of all localized structures of interest, what remains can be considered as the set of only localized defective structures of interest. Such technique can be referred to as subtractive localization.

In this way, defective instantiations of the structure of interest can be accurately or reliably localized, notwithstanding the above-mentioned unconstrained defective state-space that plaques existing techniques.

Various embodiments described herein can be considered as a computerized tool (e.g., any suitable combination of computer-executable hardware or computer-executable software) that can facilitate subtractive defect localization for charged-particle microscopy. In various aspects, such computerized tool can comprise an access component, a non-defect component, a defect-agnostic component, or a subtraction component.

In various embodiments, there can be a charged-particle microscope. In various aspects, the charged-particle microscope can exhibit any suitable design or construction (e.g., can be an SEM, can be a TEM, can be a dual-beam microscope). In various instances, there can be any suitable specimen (e.g., semiconductor wafer or lamella) that is loaded in the charged-particle microscope (e.g., that is currently located or positioned on an actuatable stage of the charged-particle microscope). In various cases, the specimen can have or otherwise contain multiple instantiations of any suitable structure of interest (e.g., multiple copies of a fin, multiple copies of a gate, multiple copies of a drain, multiple copies of a nanowire). In various aspects, the charged-particle microscope can electronically capture or otherwise generate an image (e.g., a two-dimensional pixel array, or a three-dimensional voxel array) of the specimen, which image can depict those multiple instantiations of the structure of interest.

In various cases, it can be desired to localize defective instantiations of the structure of interest within the image. As described herein, the computerized tool can facilitate such localization.

In various embodiments, the access component of the computerized tool can electronically access the image. For instance, the access component can electronically receive or retrieve the image from the charged-particle microscope. In some cases, the access component can be considered as a conduit through which other components of the computerized tool can electronically interact with (e.g., read, write, edit, copy, manipulate) the image.

In various embodiments, the non-defect component of the computerized tool can electronically store, maintain, control, or otherwise access a first machine learning model. In various aspects, the first machine learning model can exhibit any suitable internal architecture. In some cases, the first machine learning model can exhibit any suitable deep learning neural network internal architecture. For example, the first machine learning model can include any suitable numbers of any suitable types of layers (e.g., input layer, one or more hidden layers, output layer, any of which can be convolutional layers, dense layers, long short-term memory (LSTM) layers, non-linearity layers, pooling layers, batch normalization layers, or padding layers). As another example, the first machine learning model can include any suitable numbers of neurons in various layers (e.g., different layers can have the same or different numbers of neurons as each other). As yet another example, the first machine learning model can include any suitable activation functions (e.g., softmax, sigmoid, hyperbolic tangent, rectified linear unit) in various neurons (e.g., different neurons can have the same or different activation functions as each other). As still another example, the first machine learning model can include any suitable interneuron connections or interlayer connections (e.g., forward connections, skip connections, recurrent connections). However, in other cases, the first machine learning model can instead exhibit any suitable non-deep-learning internal architecture (e.g., support vector machine architecture, naïve Bayes architecture, decision tree architecture).

Regardless of its specific internal architecture, the first machine learning model can be configured or trained to selectively localize non-defective versions of the structure of interest in inputted images. Accordingly, the non-defect component can electronically execute the first machine learning model on the image, and such execution can yield a set of first localizations. For example, the non-defect component can feed the image to an input layer of the first machine learning model, the image can complete a forward pass through one or more hidden layers of the first machine learning model, and an output layer of the first machine learning model can calculate the set of first localizations based on activations provided by the one or more hidden layers of the first machine learning model.

In any case, the set of first localizations can be any suitable electronic data that indicate (e.g., via bounding boxes or segmentation masks) where, within the image, non-defective instantiations of the structure of interest are located (as inferred or predicted by the first machine learning model). That is, the first machine learning model can be considered as evaluating the pixels or voxels of the image, so as to distinguish between pixels or voxels that collectively make up or belong to healthy or undamaged versions of the structure of interest and pixels or voxels that instead collectively make up or belong to anything else (e.g., any other background object), and the set of first localizations can represent, indicate, or otherwise specify the locations of the former pixels or voxels.

Note that, in various instances, the first machine learning model can be trained to achieve a high level of accuracy or reliability with respect to selective localization of non-defective versions of the structure of interest. After all, as mentioned above, there can be only a few or otherwise finite number of possible healthy or undamaged appearances or constructions of the structure of interest, and whatever training dataset is used to train the first machine learning model can fully span or represent such few or otherwise finite number of possibilities.

In various embodiments, the defect-agnostic component of the computerized tool can electronically access a set of second localizations. In various aspects, the set of second localizations can be any suitable electronic data that indicate (e.g., via bounding boxes or segmentation masks) where, within the image, all instantiations of the structure of interest are located, regardless of defect status. In other words, the image can be considered as comprising pixels or voxels that collectively make up or belong to any version of the structure of interest, whether damaged or undamaged, and pixels or voxels that instead collectively make up or belong to anything else, and the set of second localizations can represent, indicate, or otherwise specify the locations of the former pixels or voxels. Note that the cardinality or size of the set of second localizations can be greater than or equal to that of the set of first localizations (e.g., the set of all versions of the structure of interest in the image can be greater than or equal to the set of only damaged versions of the structure of interest in the image).

In some embodiments, the defect-agnostic component can obtain or access the set of second localizations, by leveraging a second machine learning model.

Indeed, the defect-agnostic component can electronically store, maintain, control, or otherwise access the second machine learning model. In various aspects, the second machine learning model can exhibit any suitable internal architecture. In some cases, the second machine learning model can exhibit any suitable deep learning neural network internal architecture. For example, the second machine learning model can include any suitable numbers of any suitable types of layers (e.g., input layer, one or more hidden layers, output layer, any of which can be convolutional layers, dense layers, long short-term memory (LSTM) layers, non-linearity layers, pooling layers, batch normalization layers, or padding layers). As another example, the second machine learning model can include any suitable numbers of neurons in various layers (e.g., different layers can have the same or different numbers of neurons as each other). As yet another example, the second machine learning model can include any suitable activation functions (e.g., softmax, sigmoid, hyperbolic tangent, rectified linear unit) in various neurons (e.g., different neurons can have the same or different activation functions as each other). As still another example, the second machine learning model can include any suitable interneuron connections or interlayer connections (e.g., forward connections, skip connections, recurrent connections). However, in other cases, the second machine learning model can instead exhibit any suitable non-deep-learning internal architecture (e.g., support vector machine architecture, naïve Bayes architecture, decision tree architecture).

Regardless of its specific internal architecture, the second machine learning model can be configured or trained to localize any versions of the structure of interest in inputted images, without regard to defectiveness or damage. Accordingly, the defect-agnostic component can electronically execute the second machine learning model on the image, and such execution can yield the set of second localizations. For example, the defect-agnostic component can feed the image to an input layer of the second machine learning model, the image can complete a forward pass through one or more hidden layers of the second machine learning model, and an output layer of the second machine learning model can calculate the set of second localizations based on activations provided by the one or more hidden layers of the second machine learning model.

Note that, in various instances, the second machine learning model can be trained to achieve a high level of accuracy or reliability with respect to defect-agnostic localization of the structure of interest. Indeed, as mentioned above, there can be only a few or otherwise finite number of possible healthy or undamaged appearances or constructions of the structure of interest, and whatever training dataset is used to train the second machine learning model can fully span or represent such few or otherwise finite number of possibilities. This can allow or enable the second machine learning model to accurately or reliably recognize non-defective versions of the structure of interest, just like the first machine learning model. Now, as mentioned above, there can instead be an effectively infinite number of possible unhealthy or damaged appearances or constructions of the structure of interest which cannot be fully spanned or represented by whatever training dataset is used to train the second machine learning model. This is why existing techniques that implement defect-selective localization can exhibit reduced or stunted efficacy. However, as the present inventors realized, it can nevertheless be the case that all unhealthy or damaged versions of the structure of interest are still recognizable as being the structure of interest. In other words, even a uniquely defective version of the structure of interest that has never before been seen or encountered by the second machine learning model can nevertheless be considered as having a strong visual resemblance to at least some of the versions, whether defective or undefective, of the structure of interest that are included in whatever training dataset is used to train the second machine learning model. In still other words, the defect-selective machine learning models of existing techniques can be considered as attempting to recognize extremely subtle visual distinctions (e.g., distinguishing between: defective versions of the structure of interest; and non-defective versions of the structure of interest or any other background objects), which renders lack of training dataset diversity much more problematic; whereas the second machine learning model as described herein can instead be considered as attempting to recognize significantly less subtle visual distinctions (e.g., distinguishing between: any version of the structure of interest; and any other background objects), which renders lack of training dataset diversity much less problematic.

For example, consider a never-before-seen defective version of the structure of interest that is more visually similar to the non-defective versions that are included in the training dataset than to the defective versions that are included in the training dataset. Since a defect-selective machine learning model of existing techniques would be trained to ignore objects that look like the non-defective versions that are included in the training dataset, the defect-selective machine learning model would wrongly ignore or not localize that never-before-seen defective version of the structure of interest. In stark contrast, because the second machine learning model can instead be trained to localize objects that look either like the defective versions or the non-defective versions in the training dataset, the second machine learning model would instead correctly localize that never-before-seen defective version of the structure of interest.

In this way, the second machine learning model can achieve a high level of defect-agnostic localization accuracy or reliability.

In other embodiments, the defect-agnostic component can obtain or access the set of second localizations, by instead reading an electronic design file associated with the specimen.

Indeed, in various aspects, the electronic design file can be any suitable electronic file or electronic document in accordance with or otherwise based on which the specimen was manufactured or fabricated. In various instances, the electronic design file can exhibit any suitable format (e.g., graphical design file (GDS) format, CAD format, SolidWorks® format, AutoCAD® format). In various cases, the electronic design file can thus be considered as specifying a desired, ideal, or otherwise required design or construction of the specimen, and thus of the structure of interest. In various aspects, the desired, ideal, or otherwise required locations of all copies of the structure of interest within the specimen can be specified in or by the electronic design file. In various instances, the defect-agnostic component can electronically read, parse, or otherwise extract such information from the electronic design file, and the result of such reading, parsing, or extraction can be considered as the set of second localizations.

In even other embodiments, the defect-agnostic component can obtain or access the set of second localizations, by instead leveraging an example image associated with the specimen.

Indeed, as mentioned above, there can be an electronic design file in accordance with or otherwise based on which the specimen, and thus the structure of interest, was fabricated or manufactured. In some aspects, the electronic design file can include two-dimensional or three-dimensional visual depictions of the specimen (e.g., isometric view of the specimen, side-view of the specimen, front-view of the specimen, top-view of the specimen, cross-sectional cut-out views of the specimen). In various instances, an example image of the specimen can thus be obtained from the electronic design file, where such example image is registered with, aligned with, or otherwise from the same view or perspective as the image captured by the charged-particle microscope. In various cases, the image can be considered as depicting the specimen as it actually is, whereas the example image can be considered as depicting the specimen as it is intended, desired, or otherwise required to be. Accordingly, all versions of the structure of interest that are depicted in the example image can be non-defective or undamaged. Thus, in various aspects, the defect-agnostic component can execute the first machine learning model on the example image, thereby yielding the set of second localizations. For example, the defect-agnostic component can feed the example image to an input layer of the first machine learning model, the example image can complete a forward pass through one or more hidden layers of the first machine learning model, and an output layer of the first machine learning model can calculate the set of second localizations based on activations provided by the one or more hidden layers of the first machine learning model. Although the first machine learning model can be configured to selectively localize only non-defective versions of the structure of interest, all versions in the example image can be non-defective, and thus first machine learning model can be considered as localizing all versions of the structure of interest in the example image. Because the example image can be registered with, aligned with, or otherwise from the same perspective or view as the image captured by the charged-particle microscope, execution of the first machine learning model on the example image can be considered as equivalent or tantamount to the first machine learning model defect-agnostically localizing all versions of the structure of interest in the image captured by the charged-particle microscope.

In any case, the set of first localizations can be considered as indicating the intra-image locations of only the non-defective instantiations of the structure of interest, whereas the set of second localizations can instead be considered as indicating the intra-image locations of all instantiations of the structure of interest regardless of defect status. Thus, the set of first localizations and the set of second localizations can be considered as having a non-zero intersection. Indeed, the set of first localizations can be considered as a strict subset of the set of second localizations.

In various embodiments, the subtraction component of the computerized tool can electronically generate a set of third localizations, based on the set of first localizations and based on the set of second localizations. More specifically, the subtraction component can subtract (e.g., via set subtraction) the set of first localizations from the set of second localizations. In other words, the subtract component can remove from the set of second localizations whatever localizations (e.g., whatever bounding boxes or segmentation masks) that are contained in the set of first localizations, and whatever remains in the set of second localizations after such removal can be considered or referred to as the set of third localizations. Note that the set of third localizations thus can be considered as any suitable electronic data that indicate (e.g., via bounding boxes or segmentation masks) where, within the image, defective instantiations of the structure of interest are located. After all, the set of second localizations can contain all versions of the structure of interest in the image, whereas the set of first localizations can contain only non-defective versions of the structure of interest in the image. Therefore, their difference (e.g., the set of third localizations) can contain only defective versions of the structure of interest in the image.

In this way, high defect localization accuracy or reliability can be achieved via subtractive localization.

Note that, in order for the various localizations described herein to be accurately generated, the herein-described machine learning models (e.g., the first machine learning model, the second machine learning model) should first undergo training. In various cases, the computerized tool can train such machine learning models using any suitable training paradigms (e.g., via supervised training, unsupervised training, or reinforcement learning), as described later herein.

Various embodiments described herein can be employed to use hardware or software to solve problems that are highly technical in nature (e.g., to facilitate subtractive defect localization for charged-particle microscopy), that are not abstract and that cannot be performed as a set of mental acts by a human. Further, some of the processes performed can be performed by a specialized computer (e.g., electron microscopes such as SEMs, TEMs, or dual-beam microscopes; machine learning image localizers such deep learning neural networks) for carrying out defined acts related to the field of charged-particle microscopy.

For example, such defined acts can include: accessing, by a device operatively coupled to a processor, an image captured by a charged-particle microscope, wherein the image depicts a specimen; and localizing, by the device, one or more defective instantiations of a structure of interest of the specimen, based on executing on the image a first machine learning model that is trained to localize non-defective versions of the structure of interest. In some cases, the first machine learning model can receive as input the image and produce as output a set of non-defective localizations that respectively correspond to a set of non-defective instantiations of the structure of interest depicted in the image. In various aspects, such defined acts can include: accessing, by the device, a set of defect-agnostic localizations that respectively correspond to instantiations of the structure of interest depicted in the image regardless of defect status; and subtracting, by the device, the set of non-defective localizations from the set of defect-agnostic localizations, thereby yielding the one or more defective instantiations of the structure of interest. In some instances, the accessing the set of defect-agnostic localizations can comprise: executing, by the device, on the image a second machine learning model that is trained to localize versions of the structure of interest without regard to defect status, such that the second machine learning model receives as input the image and produces as output the set of defect-agnostic localizations. In other instances, the accessing the set of defect-agnostic localizations can comprise: reading, by the device, an electronic design file associated with the specimen. In yet other instances, the accessing the set of defect-agnostic localizations can comprise: accessing, by the device, an example image associated with the specimen, wherein all versions of the structure of interest depicted in the example image are non-defective; and executing, by the device, on the example image the first machine learning model, such that the first machine learning model receives as input the example image and produces as output the set of defect-agnostic localizations.

Such defined acts are inherently computerized. Indeed, a charged-particle microscope (e.g., SEM, TEM, dual beam microscope) is a highly-technical computerized device comprising specific computerized hardware (e.g., temperature sensors, pressure sensors, voltage sensors, ion beam emitters, electron beam emitters, focusing lenses, ion detectors, electron detectors, beam apertures, fluid valves, actuatable specimen stages). A charged-particle microscope and the images that it captures cannot be implemented by the human mind, or by a human with pen and paper, in any reasonable or practicable way without computers. Furthermore, machine learning models (e.g., selective or non-selective localizers) are also inherently computerized constructs comprising specific software-oriented architectures (e.g., input layers, hidden layers, or output layers, any of which can be made up of trainable or non-trainable internal parameters such as convolutional layers or LSTM layers). Machine learning models cannot be trained or executed by the human mind, or by humans with mere pen and paper, in any reasonable or practicable way without computers. Further still, defect localization is an inherently computerized task that focuses on enabling computers to automatically locate structural or design defects or damage within charged-particle microscopy images. It would make no sense whatsoever to discuss charged-particle microscopy defect localization outside of a computerized context.

Moreover, various embodiments described herein can integrate into a practical application various teachings relating to the field of charged-particle microscopy. As explained above, existing techniques for facilitating defect localization for charged-particle microscopy images train a machine learning model to selective localize defective versions of a structure of interest. As the present inventors recognized, such existing techniques exhibit stunted or otherwise reduced localization accuracy. After all, for any given structure of interest that is fabricated or manufactured in accordance with some engineering design, there can be nearly infinite unique ways in which that structure of interest can visually appear damaged, malformed, or otherwise defective. A finite training dataset is not capable of spanning or encapsulating such infinite defect diversity. So, a machine learning model trained according to existing techniques can encounter defective versions of the structure of interest that are not visually similar to those on which the machine learning model was trained. Indeed, because various defects can be quite subtle, it is possible that some never-before-seen defective versions of the structure of interest can be more visually similar to the non-defective versions on which machine learning model of existing techniques was trained than to the defective versions on which it was trained. In such cases, the machine learning model of existing techniques will incorrectly ignore or not localize such never-before-seen defective versions of the structure of interest. Accordingly, existing techniques can be considered as suffering from reduced or stunted defect localization accuracy.

Various embodiments described herein can help to ameliorate this technical problem, by implementing subtractive defect localization for charged-particle microscopy. When given an image of a specimen, various embodiments described herein can involve executing on that given image a first machine learning model that, unlike the machine learning model of existing techniques, is trained or configured to selectively localize only non-defective (rather than defective) versions of the structure of interest. Such execution can yield a set of non-defective localizations, which can be first bonding boxes or segmentation masks showing where in the given image undamaged copies of the structure of interest are positioned. Various embodiments described herein can further involve obtaining a set of defect-agnostic localizations, which can be second bonding boxes or segmentation masks showing where in the given image all copies of the structure of interest are positioned, whether damaged or undamaged. In some instances, the set of defect-agnostic localizations can be obtained by executing on the given image a second machine learning model that is trained or configured to localize all versions of the structure of interest regardless of defect status. In other instances, the set of defect-agnostic localizations can be obtained by reading or parsing them from an electronic design file (e.g., CAD file, GDS file) in accordance with which the specimen was fabricated. In even other instances, the set of defect-agnostic localizations can be obtained by executing the first machine learning model on an example image, where the example image is registered with the given image and depicts the specimen as the specimen was ideally intended, desired, or designed to be (e.g., the example image can be obtained from the electronic design file according to which the specimen was fabricated). In any case, defective instantiations of the structure of interest can be accurately or reliably localized within the given image, by subtracting the set of non-defective localizations from the set of defect-agnostic localizations.

Indeed, the present inventors realized that a machine learning model trained according to existing techniques to selectively localize only defective instantiations of the structure of interest can suffer from stunted accuracy or reliability, due to the inability of a finite training dataset to fully span the effectively infinite or unconstrained defect state-space of the structure of interest (e.g., there can be infinitely many unique ways that the structure of interest can appear damaged). In contrast, the first machine learning model described herein can instead achieve high accuracy or reliability, since its training dataset can fully span the finite or constrained non-defect state-space of the structure of interest (e.g., there can be only a few unique ways that the structure of interest can appear undamaged). Accordingly, the set of non-defective localizations described herein can be considered as having a high likelihood of accuracy or reliability. Likewise, the set of the defect-agnostic localizations can also be considered having a high likelihood of accuracy or reliability. This is evident for situations in which the set of defect-agnostic localizations are derived from the electronic design file (e.g., via reading or via execution of the first machine learning model on the example image). However, this can also be the case for situations in which the set of defect-agnostic localizations are predicted by the second machine learning model. After all, the second machine learning model, as described herein, can be trained or configured to recognize all versions of the structure of interest, whether or not damaged. The second machine learning model can accurately or reliably localize non-defective versions of the structure of interest for the same reason as the first machine learning model (e.g., the training dataset of the second machine learning model can fully span or represent the finite non-defect state-space of the structure of interest). Moreover, the second machine learning model can accurately or reliably localize defective versions of the structure of interest, since even never-before-seen defective versions of the structure of interest are extremely likely to nevertheless be recognizable as or visually reminiscent of the structure of interest. Indeed, attempting to distinguish between the structure of interest and background objects (which the second machine learning model is configured to do) can be considered as a less difficult task which is less hampered by limited defect variability in the training dataset (e.g., never-before-seen defective versions of the structure of interest have more visual resemblance to whatever versions of the structure of interest are in the training dataset than to whatever background objects are in the training dataset). In stark contrast, attempting to distinguish between the defective versions of the structure of interest and the union of non-defective versions of the structure of interest with background objects (which the machine learning model of existing techniques is configured to do) can be considered as a trickier task which is more hampered by limited defect variability in the training dataset (e.g., never-before-seen defective versions of the structure of interest might have more visual resemblance to whatever non-defective versions are in the training dataset, which are treated by existing techniques as background objects, than to whatever defective versions are in the training dataset).

In other words, various embodiments described herein can be considered as a clever or innovative technique for improving the accuracy or reliability of defect localization for charged-particle microscopy images as compared to existing techniques.

Additionally, the counter-intuitive character of various embodiments described herein must be emphasized. Indeed, facilitating or performing defect localization by utilizing a machine learning model (e.g., the first machine learning model) that is trained or configured to selectively localize only non-defective versions of the structure of interest is highly counter-intuitive. Stated differently, when it is desired to search for or identify only defective versions of the structure of interest, it would certainly not be expected, obvious, or intuitive to achieve this desire by first localizing only non-defective versions of the structure of interest. In still other words, when given a goal or objective to search for an object A, it is completely unorthodox and counter-intuitive to accomplish this goal or objective by searching for the opposite of the object A.

For at least the above reasons, various embodiments described herein can be considered as addressing or ameliorating various problems or disadvantages that afflict existing techniques for facilitating defect localization with respect to charged-particle microscopy. Therefore, various embodiments described herein can be considered as a concrete and tangible technical improvement in the field of charged-particle microscopy. Accordingly, various embodiments described herein certainly qualify as useful and practical applications of computers.

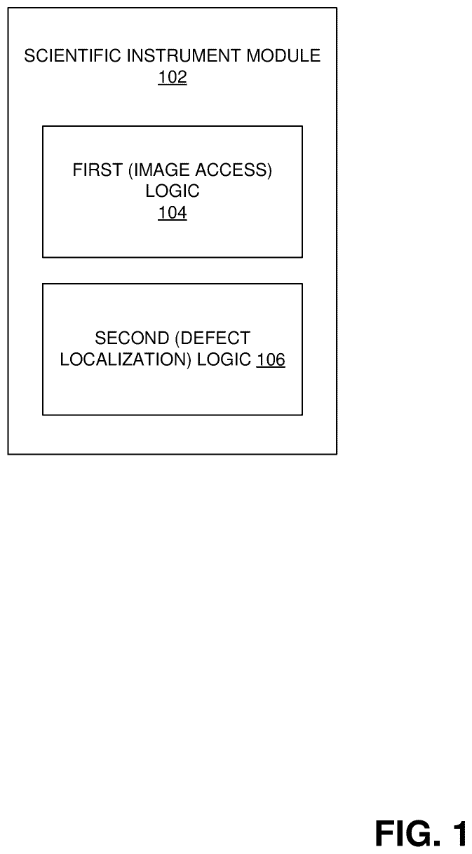

FIG. 1 illustrates an example, non-limiting block diagram of a scientific instrument module 102 in accordance with various embodiments described herein.

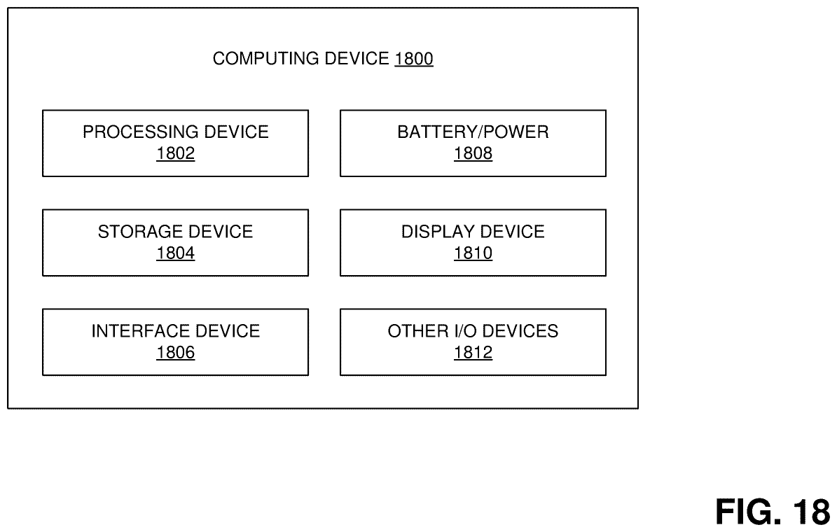

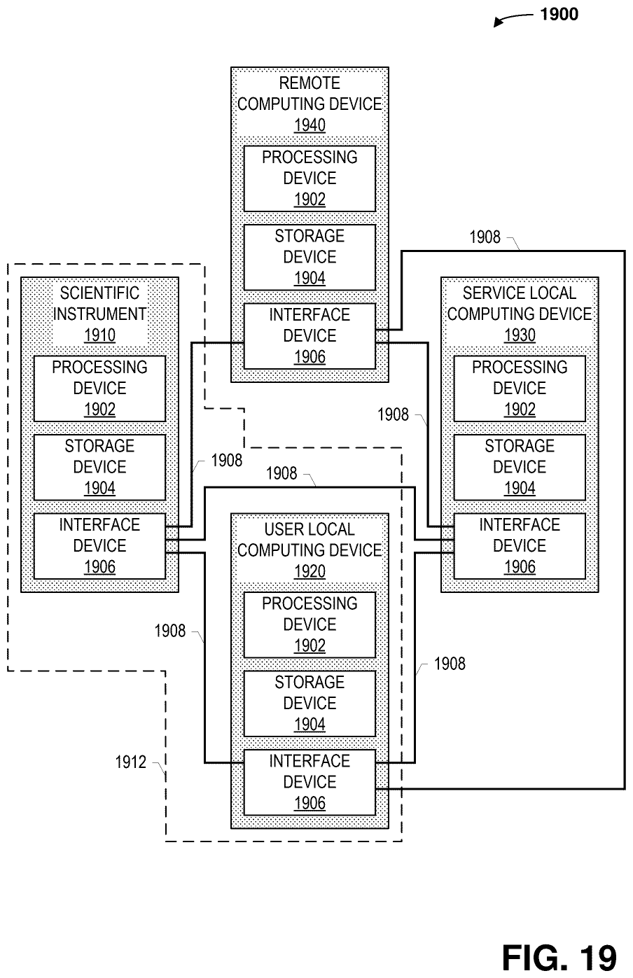

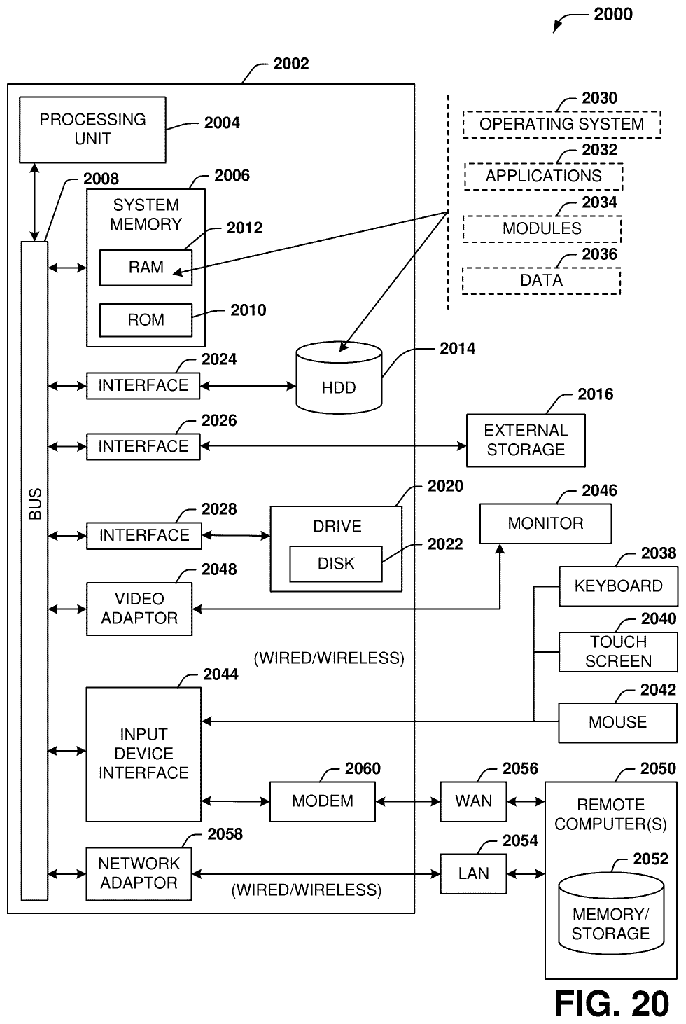

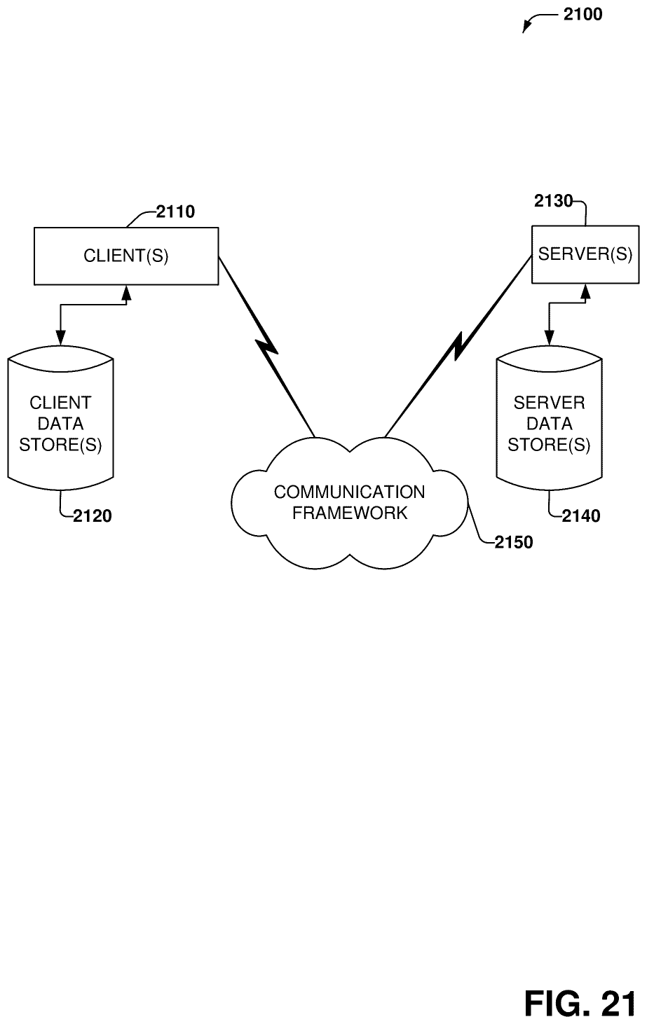

In various embodiments, the scientific instrument module 102 can be implemented by circuitry (e.g., including electrical or optical components), such as a programmed computing device. Logic of the scientific instrument module 102 can be included in a single computing device or can be distributed across multiple computing devices that are in communication with each other as appropriate. Examples of computing devices that may, singly or in combination, implement the scientific instrument module 102 are discussed herein with reference to FIGS. 18 and 20, and examples of systems or networks of interconnected computing devices, in which the scientific instrument module 102 may be implemented across one or more of the computing devices, are discussed herein with reference to FIGS. 19 and 21.

The scientific instrument module 102 can include first logic 104 and second logic 106. As used herein, the term “logic” can include an apparatus that is to perform a set of operations associated with the logic. For example, any of the logic elements included in the scientific instrument module 102 can be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” can refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices. A module can omit one or more of the logic elements depicted in the associated drawings; for example, a module may include a subset of the logic elements depicted in the associated drawings when that module is to perform a subset of the operations discussed herein with reference to that module.

In various embodiments, there can be a scientific instrument corresponding to the scientific instrument module 102. In various aspects, the scientific instrument can be any suitable computerized device that can electronically measure some scientifically-relevant, clinically-relevant, or research-relevant characteristic, property, or attribute of an analytical specimen (e.g., of a known or unknown mixture, compound, or collection of matter). As a non-limiting example, a scientific instrument can be a scanning electron microscope. In such case, the scientific instrument can capture images of the analytical specimen, so as to measure or determine a surface topography, a surface material composition, or a crystallographic structure of the analytical specimen. As another non-limiting example, a scientific instrument can be a transmission electron microscope. In such case, the scientific instrument can capture images of the interior of the analytical specimen, so as to measure or determine interior structural details of the analytical specimen. As even another non-limiting example, a scientific instrument can be a dual beam microscope. In such case, the scientific instrument can capture images of the analytical specimen in addition to being able to mill the analytical specimen. As a more general non-limiting example, a scientific instrument can be any suitable type of charged-particle microscope (e.g., some types of microscopes can use beams of non-electron ions to capture images).

In various embodiments, the first logic 104 can access an image captured or generated by the scientific instrument. In various aspects, the image can depict any suitable analytical specimen.

In various embodiments, the second logic 106 can involve localizing one or more defective instantiations of a structure of interest of the analytical specimen, based on executing on the image a first machine learning model that is trained to localize non-defective versions of the structure of interest. More specifically, execution of the first machine learning model on the image can cause the first machine learning model to produce a set of non-defective localizations, which can respectively indicate where in the image a set of non-defective instantiations of the structure of interest are located. In various aspects, the second logic 106 can involve accessing a set of defect-agnostic localizations, which can respectively indicate where in the image all instantiations of the structure of interest are located. In some instances, the second logic 106 can access the set of defect-agnostic localizations by executing a second machine learning model on the image, where the second machine learning model is trained to localize all versions of the structure of interest, regardless of defect status. In other instances, the second logic 106 can access the set of defect-agnostic localizations by reading or extracting them from an electronic design file according to which the analytical specimen was fabricated. In even other instances, the second logic 106 can access the set of defect-agnostic localizations by obtaining, from the electronic design file, an example image that depicts an idealized or defect-less version of the specimen from the same perspective or view as the image captured by the scientific instrument, and by executing the first machine learning model on the example image. In any case, the second logic 106 can subtract the set of non-defective localizations from the set of defect-agnostic localizations. The remaining localizations after such subtraction can be considered as respectively indicating where in the image the one or more defective instantiations of the structure of interest are located.

Accordingly, the scientific instrument module 102 can facilitate subtractive defect localization for charged-particle microscopy.

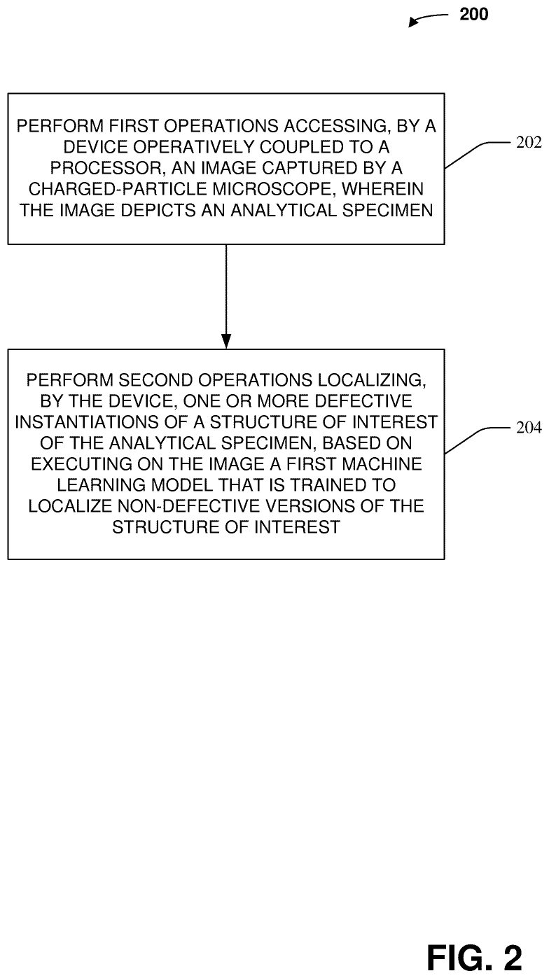

FIG. 2 is an example, non-limiting flow diagram of a computer-implemented method 200 in accordance with various embodiments described herein. The operations of the computer-implemented method 200 may be used in any suitable context to perform any suitable operations (e.g., can be performed by or used in conjunction with any of the various modules, computing devices, or graphical user interfaces described with respect to of FIGS. 1, 17, 18, 19, 20, and 21). Operations are illustrated once each and in a particular order in FIG. 2, but the operations may be reordered or repeated as desired and appropriate (e.g., different operations performed may be performed in parallel, as suitable).

In various aspects, act 202 can include performing first operations accessing, by a device operatively coupled to a processor, an image captured by a charged-particle microscope, wherein the image can depict an analytical specimen. In various cases, the first logic 104 can perform or otherwise facilitate act 202.

In various aspects, act 204 can include performing second operations localizing, by the device, one or more defective instantiations of a structure of interest of the analytical specimen, based on executing on the image a first machine learning model that is trained to localize non-defective versions of the structure of interest. In various instances, the second logic 106 can perform or otherwise facilitate act 204.

Accordingly, the computer-implemented method 200 can facilitate subtractive defect localization for charged-particle microscopy.

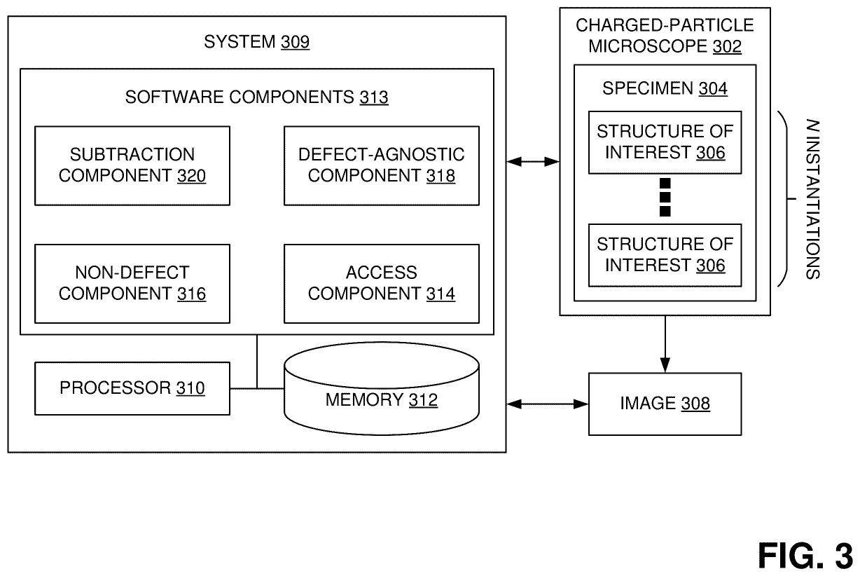

FIG. 3 illustrates a block diagram of an example, non-limiting system that can facilitate subtractive defect localization for charged-particle microscopy in accordance with one or more embodiments described herein.

In various embodiments, there can be a charged-particle microscope 302. In various aspects, the charged-particle microscope 302 can be as described above. That is, the charged-particle microscope 302 can be any suitable computerized device that can leverage its constituent hardware (e.g., electron sources, anodes, condenser lenses, condenser apertures, scan coils, objective lenses, objective apertures, deflectors, condensers, stigmators, electron detectors, X-ray detectors, actuatable specimen stages) to electronically capture any suitable image of any suitable analytical specimen. As a non-limiting example, the charged-particle microscope 302 can be any suitable SEM. As another non-limiting example, the charged-particle microscope 302 can be any suitable TEM. As yet another non-limiting example, the charged-particle microscope 302 can be any suitable dual-beam microscope.

Although not explicitly shown in the figures, the charged-particle microscope 302 can be electronically integrated with any suitable human-computer interface device, which can be remote from or local to the charged-particle microscope 302. Accordingly, a user or technician associated with the charged-particle microscope 302 can interact with or otherwise control the charged-particle microscope 302. Some non-limiting examples of the human-computer interface device can be a keyboard of the charged-particle microscope 302, a keypad of the charged-particle microscope 302, a touchscreen of the charged-particle microscope 302, or a voice-command system of the charged-particle microscope 302.

In various instances, the charged-particle microscope 302 can be loaded with a specimen 304. As a non-limiting example, the specimen 304 can be presently positioned, located, or otherwise affixed onto the specimen stage of the charged-particle microscope 302, such that the specimen 304 is analyzable or scannable by the charged-particle microscope 302. In various cases, the specimen 304 can be any suitable type of synthetic sample that can exhibit any suitable physical, chemical, compositional, or other properties, attributes, or characteristics. In various aspects, the specimen 304 can be manufactured by any suitable microfabrication or nanofabrication techniques, such as etching, milling, or deposition. As a non-limiting example, the specimen 304 can be a lamella taken from a semiconductor substrate or wafer. As another non-limiting example, the specimen 304 can be any other suitable integrated circuit element or printed circuit board element.

In any case, the specimen 304 can comprise a structure of interest 306. In various aspects, the structure of interest 306 can be any suitable physical thing that is a discrete, constituent part or portion of the specimen 304. As a non-limiting example, the structure of interest 306 can be a transistor gate that is fabricated in or on the specimen 304. As another non-limiting example, the structure of interest 306 can be a transistor fin that is fabricated in or on the specimen 304. As still another non-limiting example, the structure of interest 306 can be a transistor drain that is fabricated in or on the specimen 304. As yet another non-limiting example, the structure of interest 306 can be a nanowire that is fabricated in or on the specimen 304. In various instances, the structure of interest 306 can be repeated or duplicated n times on or in the specimen 304, for any suitable positive integer n>1. Accordingly, the specimen 304 can be considered as comprising a total of n instantiations of the structure of interest 306. In other words, there can be a total of n distinct copies of the structure of interest 306 on or in the specimen 304.

In various embodiments, the charged-particle microscope 302 can electronically capture or otherwise electronically generate an image 308 of the specimen 304. In various aspects, the image 308 can exhibit any suitable format, size, or dimensionality. As a non-limiting example, the image 308 can be an x-by-y array of pixels, for any suitable positive integers x and y. As another non-limiting example, the image 308 can be an x-by-y-by-z array of voxels, for any suitable positive integers x, y, and z. In any case, the image 308 can visually depict or illustrate the n instantiations or copies of the structure of interest 306 that are on or in the specimen 304.

In various instances, it can be desired to localize defective instantiations of the structure of interest 306 within the image 308. In other words, it can be desired to determine which of the n total instantiations of the structure of interest 306 are damaged or otherwise not shaped or constructed as they were supposed, intended, or designed to be. In various cases, a system 309 can accomplish such defect localization as described herein.

In various aspects, the system 309 can comprise a processor 310 (e.g., computer processing unit, microprocessor) and a non-transitory computer-readable memory 312 that is operably or operatively or communicatively connected or coupled to the processor 310. The non-transitory computer-readable memory 312 can store computer-executable instructions which, upon execution by the processor 310, can cause the processor 310 or other components of the system 309 (e.g., access component 314, non-defect component 316, defect-agnostic component 318, subtraction component 320) to perform one or more acts. In various embodiments, the non-transitory computer-readable memory 312 can store computer-executable components (e.g., access component 314, non-defect component 316, defect-agnostic component 318, subtraction component 320), and the processor 310 can execute the computer-executable components.

In various embodiments, the system 309 can comprise an access component 314. In various aspects, the access component 314 can electronically access the image 308. That is, the access component 314 can electronically receive, electronically retrieve, or otherwise electronically obtain the image 308, from any suitable electronic source or database. As a non-limiting example, the access component 314 can electronically obtain the image 308 from the charged-particle microscope 302 or from a computerized workstation that is associated with the charged-particle microscope 302. In any case, the access component 314 can be considered as a proxy or conduit through which other components of the system 309 can interact with, control, or otherwise manipulate the image 308. However, these are mere non-limiting examples. In other cases, the access component 314 can be omitted, and any other components of the system 309 can interact directly with the image 308.

In various embodiments, the system 309 can comprise a non-defect component 316. In various aspects, the non-defect component 316 can, as described herein, generate a set of non-defective localizations, by executing on the image 308 a first machine learning model that is configured to selectively localize only non-defective versions of the structure of interest 306.

In various embodiments, the system 309 can comprise a defect-agnostic component 318. In various instances, the defect-agnostic component 318 can, as described herein, generate a set of defect-agnostic localizations, by: executing on the image 308 a second machine learning model that is configured to localize all versions of the structure of interest 306 regardless of defect status; reading or parsing an electronic design file associated with the specimen 304; or executing the first machine learning model on an example or idealized image depicting the specimen 304 from the same perspective or orientation as the image 308.

In various embodiments, the system 309 can comprise a subtraction component 320. In various cases, the subtraction component 320 can, as described herein, localize one or more defective instantiations of the structure of interest 306 within the image 308, by subtracting the set of non-defective localizations from the set of defect-agnostic localizations.

Note that, in various instances, the access component 314, the non-defect component 316, the defect-agnostic component 318, and the subtraction component 320 can collectively be considered as being one or more software components 313 of the system 309. In various aspects, it should be appreciated that the one or more software components 313 are described primarily herein as comprising four components (e.g., the access component 314, the non-defect component 316, the defect-agnostic component 318, and the subtraction component 320) for ease of explanation and illustration. However, the one or more software components 313 are not limited to being implemented as exactly such four components in every embodiment. Indeed, in some embodiments, the functionalities described herein of such four components can be combined in any suitable fashions, so as to be implemented in or by fewer than four components (e.g., in some cases, a single component can perform all of the functionalities that are described herein with respect to the access component 314, the non-defect component 316, the defect-agnostic component 318, and the subtraction component 320). In other embodiments, the functionalities described herein of such four components can instead be distributed, separated, split, or fragmented in any suitable fashions, so as to be implemented in or by more than four components (e.g., two or more components can facilitate the functionalities that are performable by the access component 314; two or more components can facilitate the functionalities that are performable by the non-defect component 316; two or more components can facilitate the functionalities that are performable by the defect-agnostic component 318; two or more components can facilitate the functionalities that are performable by the subtraction component 320).

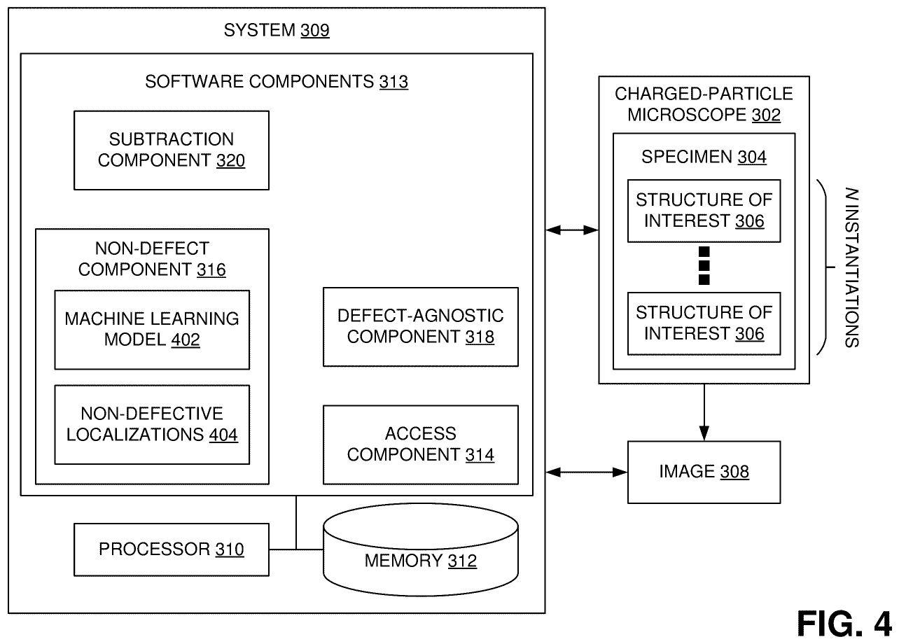

FIG. 4 illustrates a block diagram of an example, non-limiting system including a first machine learning model and a set of non-defective localizations that can facilitate subtractive defect localization for charged-particle microscopy in accordance with one or more embodiments described herein.

In various embodiments, the non-defect component 316 can electronically store, electronically maintain, electronically control, or otherwise electronically access a machine learning model 402. In various aspects, the machine learning model 402 can exhibit any suitable internal architecture.

In some cases, the machine learning model 402 can exhibit any suitable deep learning neural network internal architecture. Indeed, in various cases, the machine learning model 402 can have an input layer, one or more hidden layers, and an output layer. In various instances, any of such layers can be coupled together by any suitable interneuron connections or interlayer connections, such as forward connections, skip connections, or recurrent connections. Furthermore, in various cases, any of such layers can be any suitable types of neural network layers having any suitable learnable or trainable internal parameters. For example, any of such input layer, one or more hidden layers, or output layer can be convolutional layers, whose learnable or trainable parameters can be convolutional kernels. As another example, any of such input layer, one or more hidden layers, or output layer can be dense layers, whose learnable or trainable parameters can be weight matrices or bias values. As still another example, any of such input layer, one or more hidden layers, or output layer can be batch normalization layers, whose learnable or trainable parameters can be shift factors or scale factors. As even another example, any of such input layer, one or more hidden layers, or output layer can be LSTM layers, whose learnable or trainable parameters can be input-state weight matrices or hidden-state weight matrices. As yet another example, any of such input layer, one or more hidden layers, or output layer can be transformer layers, whose learnable or trainable parameters can be single-head or multi-head attention blocks or other weight matrices. Further still, in various cases, any of such layers can be any suitable types of neural network layers having any suitable fixed or non-trainable internal parameters. For example, any of such input layer, one or more hidden layers, or output layer can be non-linearity layers, padding layers, pooling layers, or concatenation layers.

In other cases, the machine learning model 402 can exhibit any other suitable internal architecture. As a non-limiting example, the machine learning model 402 can, in some aspects, exhibit a support vector machine internal architecture. As another non-limiting example, the machine learning model 402 can, in some aspects, exhibit a naïve Bayes internal architecture. As even another non-limiting example, the machine learning model 402 can, in some aspects, exhibit a decision tree or random forest internal architecture.

In some cases, the internal architecture of the machine learning model 402 can be any suitable combination of any of the aforementioned.

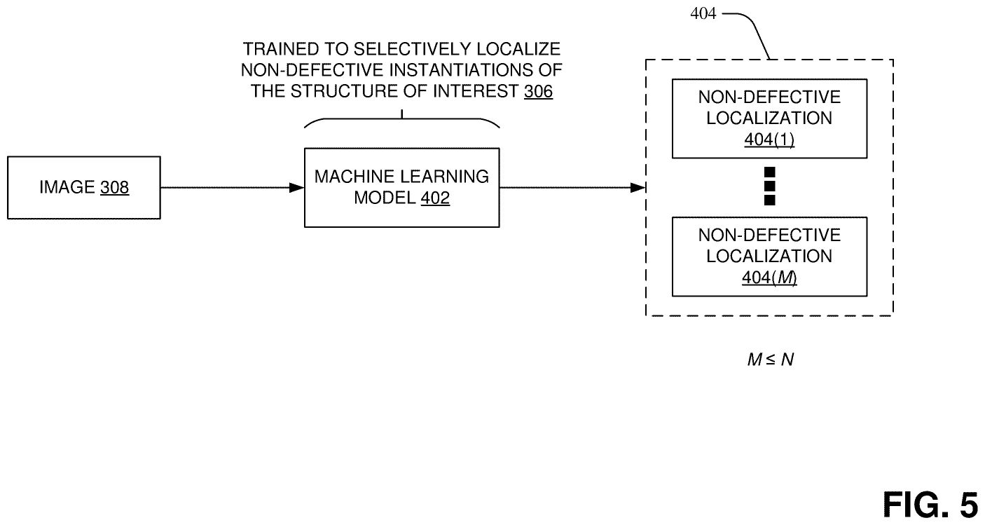

Regardless of its specific internal architecture (e.g., of its specific numbers, types, or organizations of layers), the machine learning model 402 can be configured or trained to selectively localize non-defective versions of the structure of interest 306. Accordingly, in various aspects, the non-defect component 316 can electronically leverage the machine learning model 402, so as to generate a set of non-defective localizations 404 based on the image 308. Non-limiting aspects are described with respect to FIG. 5.

FIG. 5 illustrates an example, non-limiting block diagram showing how the machine learning model 402 can produce the set of non-defective localizations 404 in accordance with one or more embodiments described herein.

In various embodiments, the non-defect component 316 can electronically execute the machine learning model 402 on the image 308. In various aspects, such execution can cause the machine learning model 402 to produce the set of non-defective localizations 404. As a non-limiting example, the non-defect component 316 can feed the image 308 to an input layer of the machine learning model 402, the image 308 can complete a forward pass through one or more hidden layers of the machine learning model 402, and an output layer of the machine learning model 402 can compute or calculate the set of non-defective localizations 404 based on activation maps or feature maps produced by the one or more hidden layers of machine learning model 402.

In any case, the set of non-defective localizations 404 can be any suitable electronic data that indicate, convey, specify, or otherwise represent where (in the opinion of the machine learning model 402) respective non-defective instantiations of the structure of interest 306 are located within the image 308. More specifically, the set of non-defective localizations 404 can comprise m localizations, for any suitable positive integer m≤n: a non-defective localization 404(1) to a non-defective localization 404(m). In various aspects, each of the set of non-defective localizations 404 can be one or more scalars, one or more vectors, one or more matrices, one or more tensors, or any suitable combination thereof that indicates or otherwise represents an intra-image location within the image 308 of a respective non-defective instantiation of the structure of interest 306. In some cases, each of the set of non-defective localizations 404 can be a bounding box indicating a respective intra-image location. In other cases, each of the set of non-defective localizations 404 can instead be a segmentation mask indicating a respective intra-image location. As a non-limiting example, the machine learning model 402 can infer or predict that a first instantiation of the n total instantiations of the structure of interest 306 that are depicted in the image 308 is non-defective (e.g., is undamaged, is healthy, is otherwise constructed as intended or designed), and the non-defective localization 404(1) can be a first bounding box or a first segmentation mask that circumscribes or covers whichever pixels or voxels of the image 308 that the machine learning model 402 has inferred or predicted belong to or make up that first non-defective instantiation. As another non-limiting example, the machine learning model 402 can infer or predict that an m-th instantiation of the n total instantiations of the structure of interest 306 that are depicted in the image 308 is non-defective, and the non-defective localization 404(m) can be an m-th bounding box or an m-th segmentation mask that circumscribes or covers whichever pixels or voxels of the image 308 that the machine learning model 402 has inferred or predicted belong to or make up that m-th non-defective instantiation.

In other words, the machine learning model 402 can be considered as being able to visually distinguish between pixels or voxels of the image 308 that depict non-defective copies of the structure of interest 306 and pixels or voxels of the image 308 that instead depict anything else, and the set of non-defective localizations 404 can respectively indicate the intra-image locations or positions of the former group of pixels or voxels.

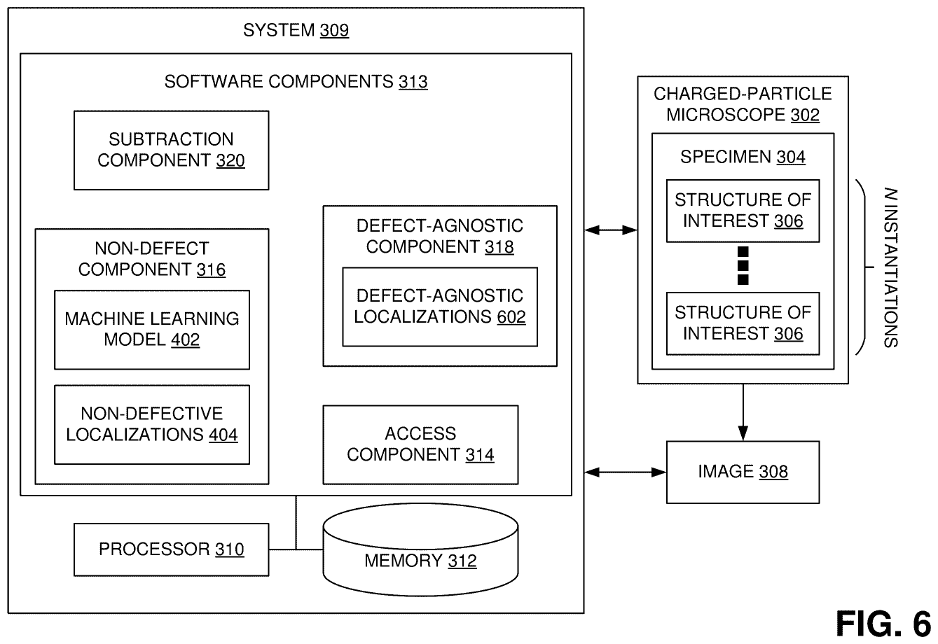

FIG. 6 illustrates a block diagram of an example, non-limiting system including a set of defect-agnostic localizations that can facilitate subtractive defect localization for charged-particle microscopy in accordance with one or more embodiments described herein.

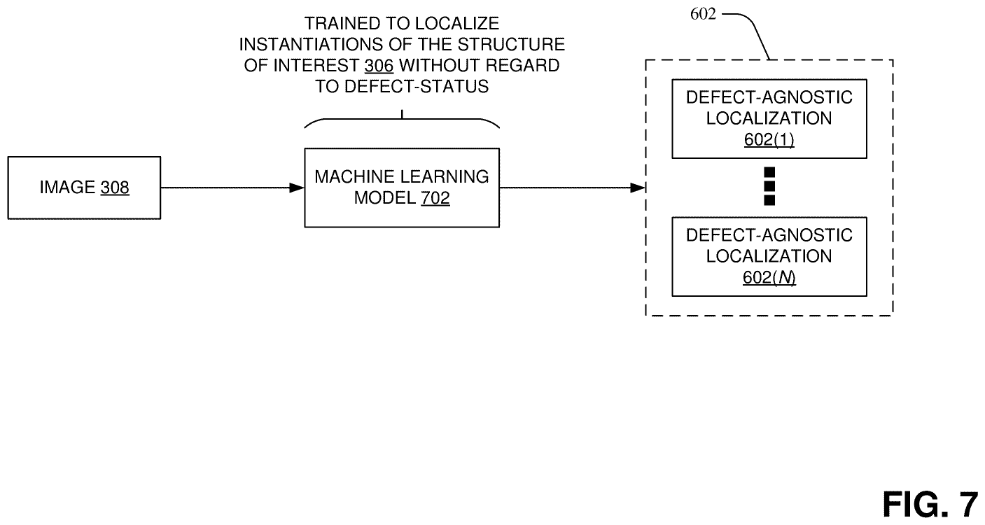

In various embodiments, the defect-agnostic component 318 can electronically obtain or otherwise electronically access a set of defect-agnostic localizations 602. In various aspects, the set of defect-agnostic localizations 602 can be any suitable electronic data that indicate, convey, specify, or otherwise represent where the n total instantiations of the structure of interest 306 are located within the image 308. In other words, the set of defect-agnostic localizations 602 can show the intra-image locations or positions of all versions or copies of the structure of interest 306, without regard to defect status, hence the term “defect-agnostic”. In some cases, the defect-agnostic component 318 can obtain or access the set of defect-agnostic localizations 602 by leveraging another machine learning model. In other cases, the defect-agnostic component 318 can obtain or access the set of defect-agnostic localizations 602 by leveraging an electronic design file associated with the specimen 304. In yet other cases, the defect-agnostic component 318 can obtain or access the set of defect-agnostic localizations 602 by leveraging the machine learning model 402 and an example image of the specimen 304. Non-limiting aspects are described with respect to FIGS. 7-9.

FIGS. 7-9 illustrate example, non-limiting block diagrams showing how the set of defect-agnostic localizations 602 can be obtained in accordance with one or more embodiments described herein.

First, consider FIG. 7. In various embodiments, the defect-agnostic

component 318 can electronically store, electronically maintain, electronically control, or otherwise electronically access a machine learning model 702. In various aspects, the machine learning model 702 can exhibit any suitable internal architecture.

In some cases, the machine learning model 702 can exhibit any suitable deep learning neural network internal architecture. Indeed, in various cases, the machine learning model 702 can have an input layer, one or more hidden layers, and an output layer. In various instances, any of such layers can be coupled together by any suitable interneuron connections or interlayer connections, such as forward connections, skip connections, or recurrent connections. Furthermore, in various cases, any of such layers can be any suitable types of neural network layers having any suitable learnable or trainable internal parameters. For example, any of such input layer, one or more hidden layers, or output layer can be convolutional layers, whose learnable or trainable parameters can be convolutional kernels. As another example, any of such input layer, one or more hidden layers, or output layer can be dense layers, whose learnable or trainable parameters can be weight matrices or bias values. As still another example, any of such input layer, one or more hidden layers, or output layer can be batch normalization layers, whose learnable or trainable parameters can be shift factors or scale factors. As even another example, any of such input layer, one or more hidden layers, or output layer can be LSTM layers, whose learnable or trainable parameters can be input-state weight matrices or hidden-state weight matrices. As yet another example, any of such input layer, one or more hidden layers, or output layer can be transformer layers, whose learnable or trainable parameters can be single-head or multi-head attention blocks or other weight matrices. Further still, in various cases, any of such layers can be any suitable types of neural network layers having any suitable fixed or non-trainable internal parameters. For example, any of such input layer, one or more hidden layers, or output layer can be non-linearity layers, padding layers, pooling layers, or concatenation layers.

In other cases, the machine learning model 702 can exhibit any other suitable internal architecture. As a non-limiting example, the machine learning model 702 can, in some aspects, exhibit a support vector machine internal architecture. As another non-limiting example, the machine learning model 702 can, in some aspects, exhibit a naïve Bayes internal architecture. As even another non-limiting example, the machine learning model 702 can, in some aspects, exhibit a decision tree or random forest internal architecture.

In some cases, the internal architecture of the machine learning model 702 can be any suitable combination of any of the aforementioned.

Regardless of its specific internal architecture (e.g., of its specific numbers, types, or organizations of layers), the machine learning model 702 can be configured or trained to non-selectively localize all versions of the structure of interest 306 without regard to defect status. In other words, the machine learning model 702 can be agnostic to defects, such that it can localize both non-defective instantiations and defective instantiations of the structure of interest 306. Accordingly, in various aspects, the defect-agnostic component 318 can electronically leverage the machine learning model 702, so as to generate a set of defect-agnostic localizations 602 based on the image 308.

Indeed, in various embodiments, the defect-agnostic component 318 can electronically execute the machine learning model 702 on the image 308. In various aspects, such execution can cause the machine learning model 702 to produce the set of defect-agnostic localizations 602. As a non-limiting example, the defect-agnostic component 318 can feed the image 308 to an input layer of the machine learning model 702, the image 308 can complete a forward pass through one or more hidden layers of the machine learning model 702, and an output layer of the machine learning model 702 can compute or calculate the set of defect-agnostic localizations 602 based on activation maps or feature maps produced by the one or more hidden layers of machine learning model 702.

In any case, as mentioned above, the set of defect-agnostic localizations 602 can be any suitable electronic data that indicate, convey, specify, or otherwise represent where all (both defective and non-defective) instantiations of the structure of interest 306 are located within the image 308. More specifically, since the image 308 can depict or illustrate the n total instantiations of the structure of interest 306 that are in or on the specimen 304, the set of defect-agnostic localizations 602 can comprise n localizations: a defect-agnostic localization 602(1) to a defect-agnostic localization 602(n). In various aspects, each of the set of defect-agnostic localizations 602 can be one or more scalars, one or more vectors, one or more matrices, one or more tensors, or any suitable combination thereof that indicates or otherwise represents an intra-image location within the image 308 of a respective instantiation of the structure of interest 306. In some cases, each of the set of defect-agnostic localizations 602 can be a bounding box indicating a respective intra-image location. In other cases, each of the set of defect-agnostic localizations 602 can instead be a segmentation mask indicating a respective intra-image location. As a non-limiting example, the defect-agnostic localization 602(1) can be a first bounding box or a first segmentation mask that circumscribes or covers whichever pixels or voxels of the image 308 that belong to or make up the first instantiation (no matter defective or non-defective) of the structure of interest 306 that is depicted in the image 308. As another non-limiting example, the defect-agnostic localization 602(n) can be an n-th bounding box or an n-th segmentation mask that circumscribes or covers whichever pixels or voxels of the image 308 that belong to or make up the n-th instantiation (no matter defective or non-defective) of the structure of interest 306 that is depicted in the image 308.

In other words, the machine learning model 702 can be considered as being able to visually distinguish between pixels or voxels of the image 308 that depict any copy (whether defective or non-defective) of the structure of interest 306 and pixels or voxels of the image 308 that instead depict anything else, and the set of defect-agnostic localizations 602 can respectively indicate the intra-image locations or positions of the former group of pixels or voxels.

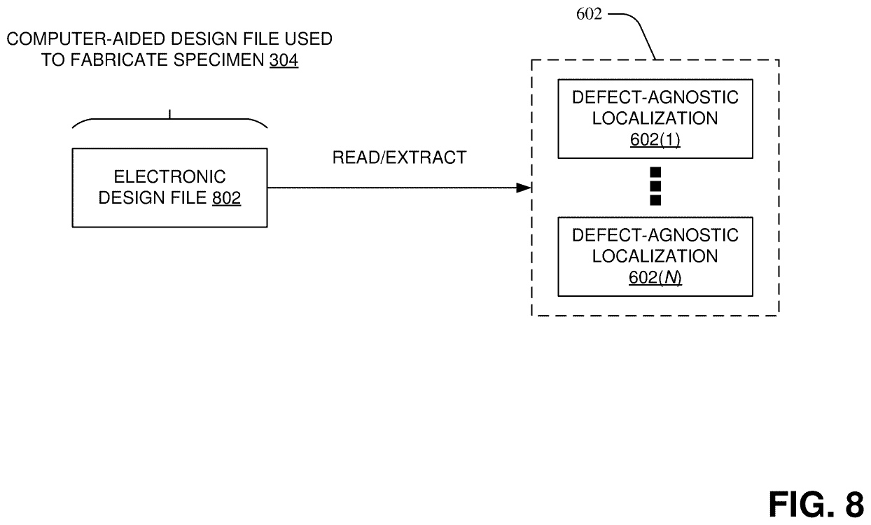

Next, consider FIG. 8. In various embodiments, rather than leveraging the machine learning model 702, the defect-agnostic component 318 can instead obtain or access the set of defect-agnostic localizations 602 by leveraging an electronic design file 802. In particular, the defect-agnostic component 318 can electronically receive, electronically retrieve, or otherwise electronically access the electronic design file 802 from any suitable electronic source or database. In various aspects, the electronic design file 802 can be any suitable computer file or computer document written or formatted according to any suitable syntax or coding language that can specify or otherwise indicate an engineering design according to which the specimen 304 was fabricated or manufactured. As a non-limiting example, the electronic design file 802 can be any suitable GDS file specifying a physical or engineering design or construction of the specimen 304. As another non-limiting example, the electronic design file 802 can be any suitable CAD file (e.g., SolidWorks® file, AutoCAD® file) specifying a physical or engineering design or construction of the specimen 304. In any case, the electronic design file 802 can be considered specifying how the specimen 304 is or was supposed or intended to have been constructed, fabricated, or manufactured. Accordingly, the electronic design file 802 can, in some instances, be considered as specifying, conveying, or otherwise indicating where within the specimen 304 the n total instantiations of the structure of interest 306 are supposed, intended, or desired to have been formed, located, or positioned. In other words, the electronic design file 802 can, in some instances, be considered as specifying, conveying, or otherwise indicating the set of defect-agnostic localizations 602. Thus, in various aspects, the defect-agnostic component 318 can electronically read or extract, via any suitable computer file parsing techniques, the set of defect-agnostic localizations 602 from the electronic design file 802.

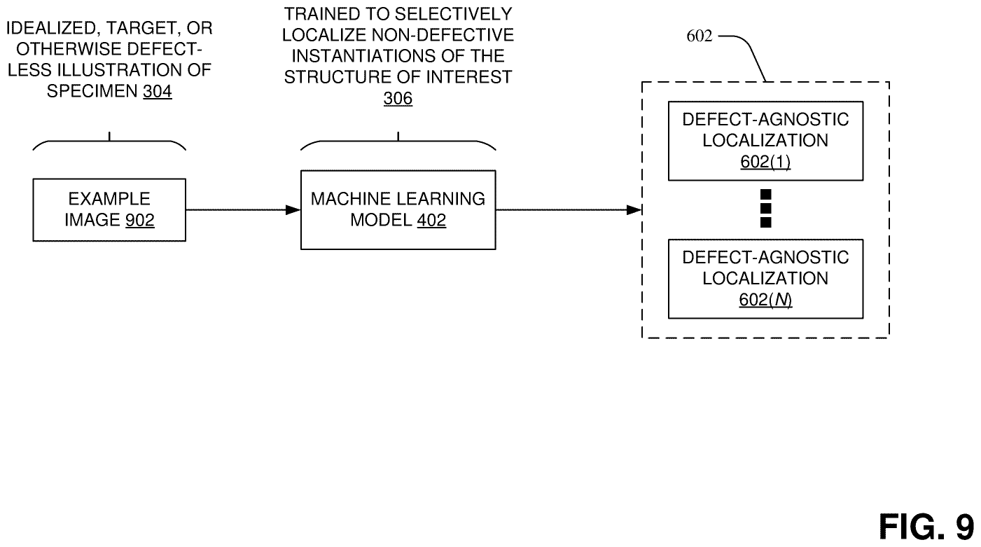

Now, consider FIG. 9. In various embodiments, the defect-agnostic component 318 can instead obtain or access the set of defect-agnostic localizations 602 by leveraging the machine learning model 402 and an example image 902. In various aspects, the defect-agnostic component 318 can electronically receive, electronically retrieve, or otherwise electronically access the example image 902 from any suitable electronic source or database. In various instances, the example image 902 can be any suitable image that depicts or illustrates the specimen 304 from the same perspective or view as the image 308, but that does so in an idealized, target, or otherwise defect-less fashion. In other words, the example image 902 can depict the n total instantiations of the structure of interest 306 such that they are in the same respective or relative intra-image locations or positions as shown in the image 308, and such that they are all non-defective.

As a non-limiting example, consider again the electronic design file 802. In some cases, the electronic design file 802 can comprise any suitable two-dimensional or three-dimensional idealized or defect-less visual depictions or illustrations of the specimen 304. For instance, the electronic design file 802 can comprise an idealized or defect-less isometric view of the specimen 304, an idealized or defect-less side-view of the specimen 304, an idealized or defect-less front-view of the specimen 304, an idealized or defect-less top-view of the specimen 304, or any suitable idealized or defect-less cross-sectional cut-out views of the specimen 304. Accordingly, by applying any suitable image matching or image registration techniques, the defect-agnostic component 318 can identify within the electronic design file 802 an idealized or defect-less image of the specimen 304 that is aligned with, or otherwise from the same perspective or view direction as, the image 308. Such idealized or defect-less image can be referred to as the example image 902.

In various aspects, the defect-agnostic component 318 can electronically execute the machine learning model 402 on the example image 902. In various instances, such execution can cause the machine learning model 402 to produce the set of defect-agnostic localizations 602. As a non-limiting example, the defect-agnostic component 318 can feed the example image 902 to an input layer of the machine learning model 402, the example image 902 can complete a forward pass through one or more hidden layers of the machine learning model 402, and an output layer of the machine learning model 402 can compute or calculate the set of defect-agnostic localizations 602 based on activation maps or feature maps produced by the one or more hidden layers of machine learning model 402. Although the machine learning model 402 can, as described above, be trained or configured to selectively localize only non-defective versions of the structure of interest 306, the example image 902 can depict all n instantiations of the structure of interest 306 as being non-defective. Accordingly, the machine learning model 402 can be able to localize all n instantiations of the structure of interest 306 within the example image 902. In since the example image 902 can be aligned or registered with the image 308, the localizations produced by the machine learning model 402 based on the example image 902 can be considered as being equally applicable to the image 308.

No matter how the defect-agnostic component 318 obtains or accesses the set of defect-agnostic localizations 602, the set of defect-agnostic localizations 602 can be considered as indicating the respective intra-image locations or positions within the image 308 of all n instantiations of the structure of interest 306.

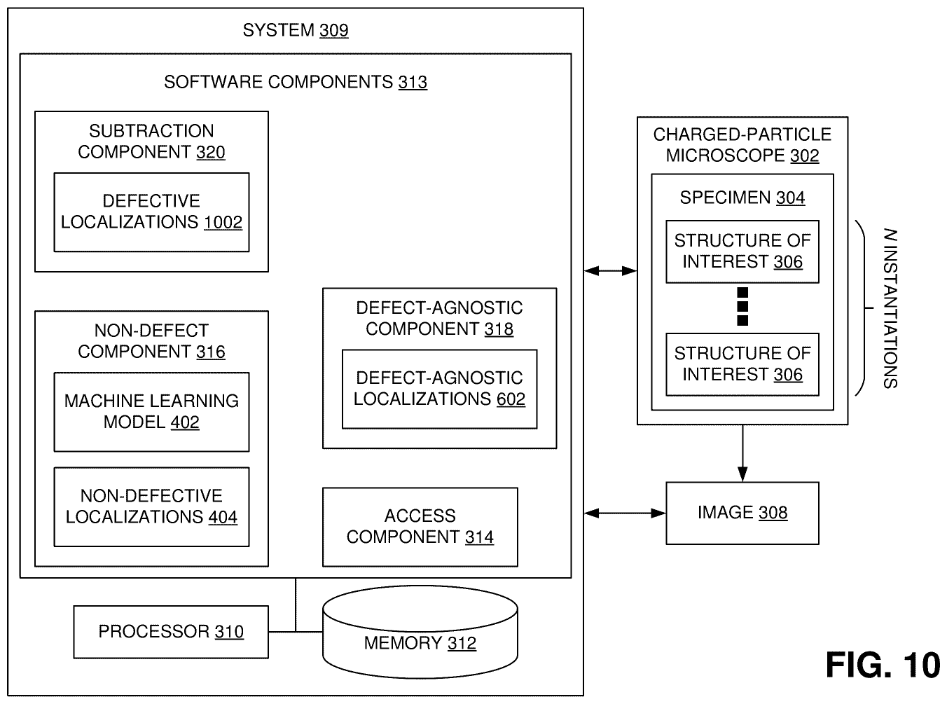

FIG. 10 illustrates a block diagram of an example, non-limiting system including a set of defective localizations that can facilitate subtractive defect localization for charged-particle microscopy in accordance with one or more embodiments described herein.

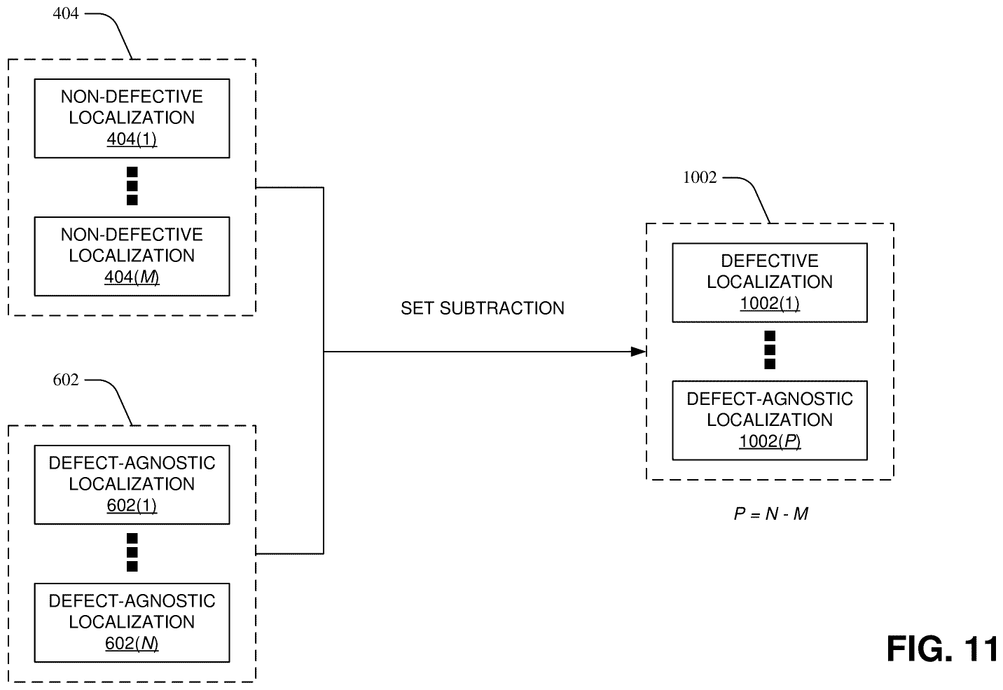

In various embodiments, the subtraction component 320 can electronically generate a set of defective localizations 1002, based on the set of non-defective localizations 404 and the set of defect-agnostic localizations 602. Non-limiting aspects are described with respect to FIG. 11.

FIG. 11 illustrates an example, non-limiting block diagram showing how the set of defective localizations 1002 can be obtained based on the set of non-defective localizations 404 and the set of defect-agnostic localizations 602 in accordance with one or more embodiments described herein.

In various embodiments, the subtraction component 320 can electronically generate the set of defective localizations 1002, by subtracting, via set subtraction, the set of non-defective localizations 404 from the set of defect-agnostic localizations 602. More specifically, in various instances, the subtraction component 320 can electronically iterate through the set of defect-agnostic localizations 602. For each given defect-agnostic localization in the set of defect-agnostic localizations 602, the subtraction component 320 can determine whether or not that given defect-agnostic localization matches (e.g., according to any suitable threshold margin of similarity) any of the set of non-defective localizations 404. If not, the subtraction component 320 can maintain or preserve that given defect-agnostic localization. If so, the subtraction component 320 can instead discard or eliminate that given defect-agnostic localization. The subtraction component 320 can then iterate to a next defect-agnostic localization in the set of defect-agnostic localizations 602. Whichever of the set of defect-agnostic localizations 602 remain or are maintained or preserved after the subtraction component 320 has iterated through all of the set of defect-agnostic localizations 602 can be considered or referred to as the set of defective localizations 1002.

As a non-limiting example, the set of defective localizations 1002 can begin or be initialized as an empty or null set. Let i be an integer that incrementally ranges from 1 to n. In various aspects, the subtraction component 320 can determine whether a defect-agnostic localization 602(i) matches (e.g., is a bounding box or segmentation mask that has at least a threshold amount of spatial or areal overlap with) any of the set of non-defective localizations 404. If the defect-agnostic localization 602(i) matches (e.g., circumscribes or covers at least a threshold number of the same pixels or voxels as) any of the set of non-defective localizations 404, then the subtraction component 320 can conclude that the defect-agnostic localization 602(i) indicates the intra-image localization of a non-defective instantiation of the structure of interest 306, and the subtraction component 320 can accordingly refrain from inserting the defect-agnostic localization 602(i) into the set of defective localizations 1002. On the other hand, if the defect-agnostic localization 602(i) does not match any of the set of non-defective localizations 404, then the subtraction component 320 can instead conclude that the defect-agnostic localization 602(i) indicates the intra-image localization of a defective instantiation of the structure of interest 306, and the subtraction component 320 can accordingly insert the defect-agnostic localization 602(i) into the set of defective localizations 1002. By iterating through all integers i from 1 to n in this fashion, the subtraction component 320 can incrementally build the set of defective localizations 1002.

In any case, the set of defective localizations 1002 can be any suitable electronic data that indicate, convey, specify, or otherwise represent where respective defective instantiations of the structure of interest 306 are located within the image 308. More specifically, the set of defective localizations 1002 can comprise p localizations, where p=n−m: a defective localization 1002(1) to a defective localization 1002(p). After all, the set of defective localizations 1002 can be considered as the remainder achieved by removing the set of non-defective localizations 404 (having cardinality m) from the set of defect-agnostic localizations 602 (having cardinality n). In various aspects, each of the set of defective localizations 1002 can be one or more scalars, one or more vectors, one or more matrices, one or more tensors, or any suitable combination thereof that indicates or otherwise represents an intra-image location within the image 308 of a respective defective instantiation of the structure of interest 306. In some cases, each of the set of defective localizations 1002 can be a bounding box indicating a respective intra-image location. In other cases, each of the set of defective localizations 1002 can instead be a segmentation mask indicating a respective intra-image location. As a non-limiting example, the defective localization 1002(1) can be a first bounding box or a first segmentation mask that circumscribes or covers whichever pixels or voxels of the image 308 that belong to or make up a first defective instantiation of the structure of interest 306. As another non-limiting example, the defective localization 1002(p) can be a p-th bounding box or a p-th segmentation mask that circumscribes or covers whichever pixels or voxels of the image 308 that belong to or make up a p-th defective instantiation of the structure of interest 306.

Accordingly, as described herein, the system 309 can electronically facilitate defect localization with respect to the structure of interest 306 depicted in the image 308, by counter-intuitively leveraging a machine learning model (e.g., 402) that is trained or configured to selectively localize only non-defective versions of the structure of interest 306.

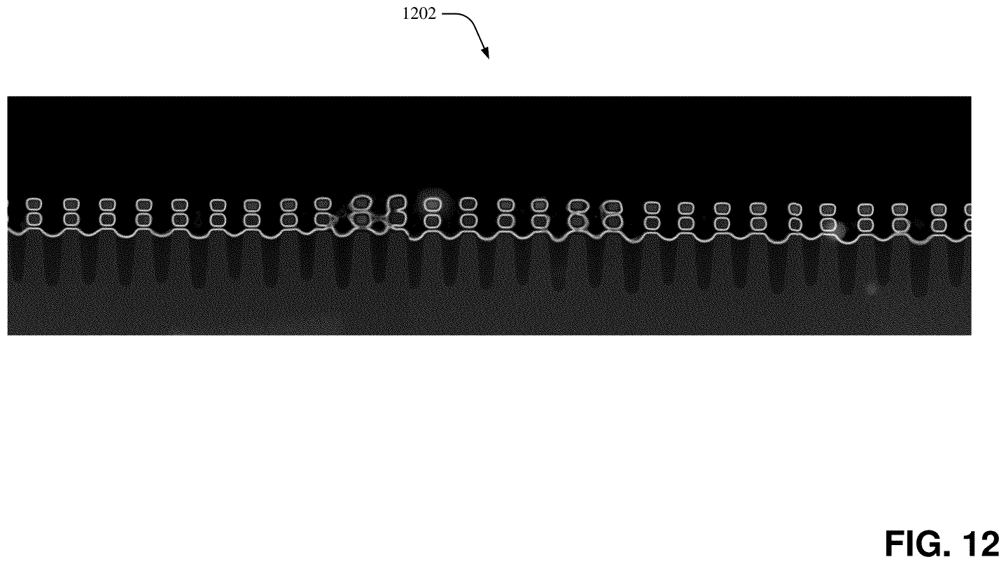

FIGS. 12-15 illustrate example, non-limiting experimental results in accordance with one or more embodiments described herein.

First, consider FIG. 12. FIG. 12 illustrates a TEM-scanned image 1202 of a semiconductor wafer containing repeated or duplicated instantiations of a nanowire. Some instantiations of the nanowire are non-defective (e.g., smooth, properly formed or shaped). However, other instantiations of the nanowire are defective (e.g., jagged or malformed).

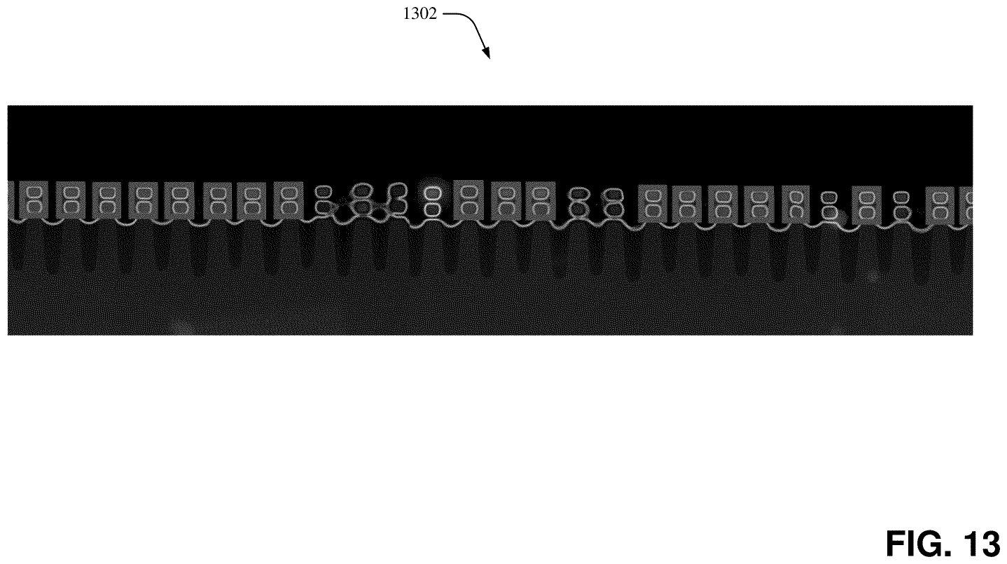

Now, consider FIG. 13. FIG. 13 illustrates a TEM-scanned image 1302. In various aspects, the TEM-scanned image 1302 was obtained by: executing the machine learning model 402 on the TEM-scanned image 1202, thereby yielding the set of non-defective localizations 404; and superimposing the set of non-defective localizations 404 over top of the TEM-scanned image 1202. In the non-limiting example of FIG. 13, the set of non-defective localizations 404 are depicted as grey bounding boxes circumscribing whatever pixels that the machine learning model 402 inferred or predicted made up non-defective instantiations of the nanowire.

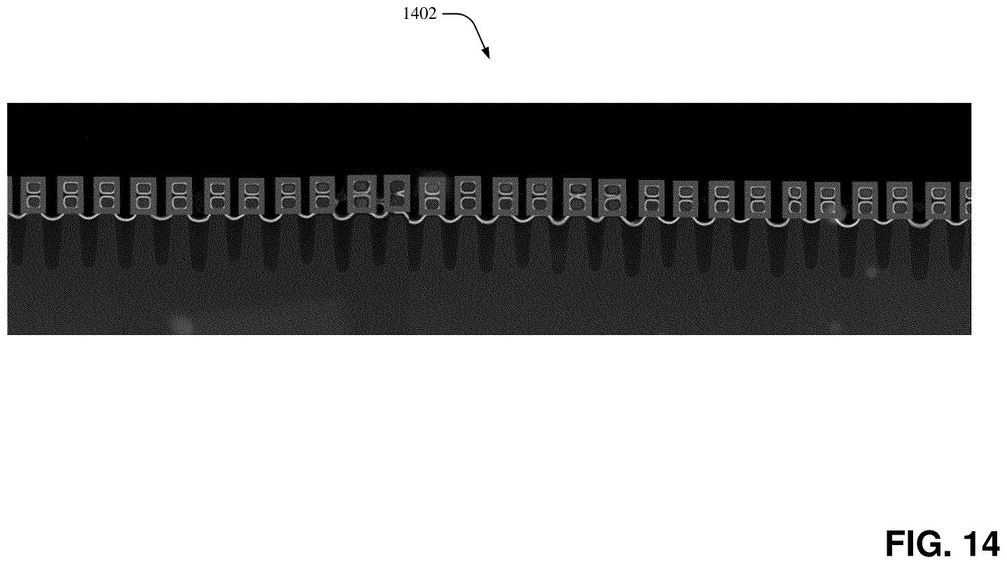

Now, consider FIG. 14. FIG. 14 illustrates a TEM-scanned image 1402. In various aspects, the TEM-scanned image 1402 was obtained by: executing the machine learning model 702 on the TEM-scanned image 1202, thereby yielding the set of defect-agnostic localizations 602; and superimposing the set of defect-agnostic localizations 602 over top of the TEM-scanned image 1202. In the non-limiting example of FIG. 14, the set of defect-agnostic localizations 602 are depicted as grey bounding boxes circumscribing whatever pixels that the machine learning model 702 inferred or predicted made up any instantiation (e.g., whether or not defective) of the nanowire.

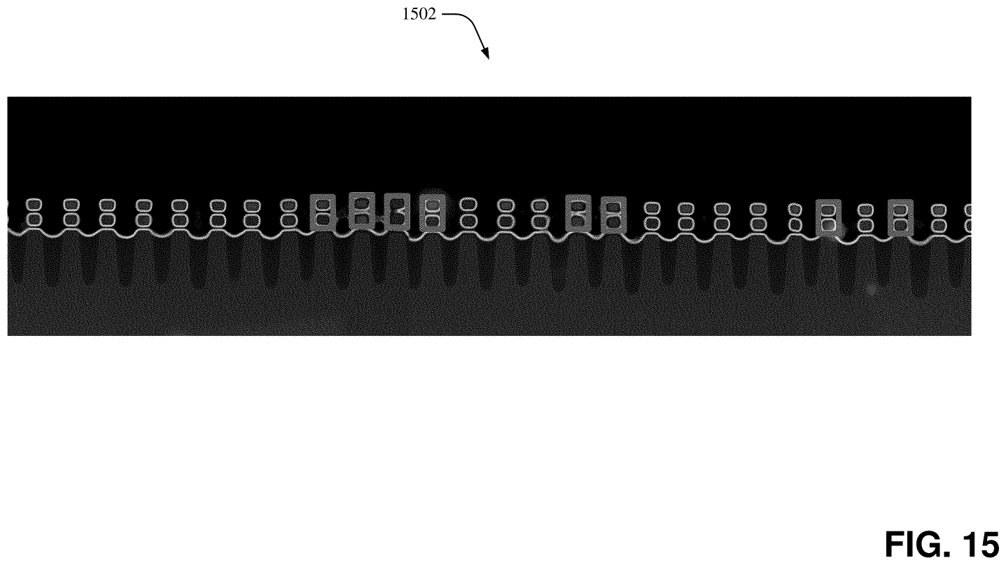

Now, consider FIG. 15. FIG. 15 illustrates a TEM-scanned image 1502. In various aspects, the TEM-scanned image 1502 was obtained by: subtracting the set of non-defective localizations 404 from the set of defect-agnostic localizations 602, thereby yielding the set of defective localizations 1002; and superimposing the set of defective localizations 1002 over top of the TEM-scanned image 1202. In the non-limiting example of FIG. 15, the set of defective localizations 1002 are depicted as grey bounding boxes circumscribing whatever pixels that the machine learning model 702 localized but that the machine learning model 402 did not localize (e.g., whatever pixels make up defective instantiations of the nanowire).

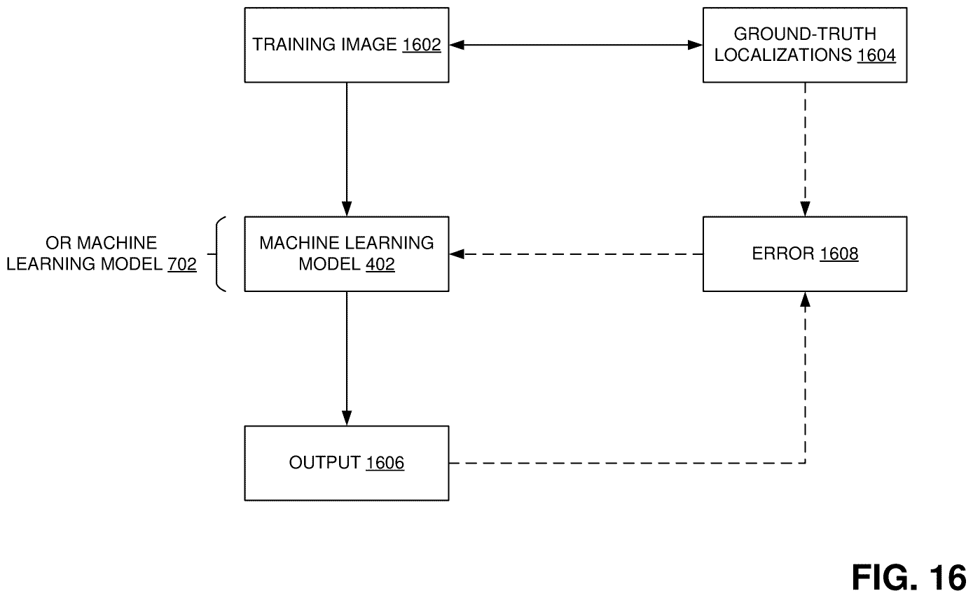

In order for the herein-described subtractive defect localization to be accurate, correct, or reliable, the various machine learning models described herein can first undergo training. A non-limiting example of such training is described with respect to FIG. 16.

FIG. 16 illustrates an example, non-limiting block diagram showing how various artificial intelligence models can be trained in accordance with one or more embodiments described herein.

In various aspects, prior to beginning training, the trainable internal parameters (e.g., convolutional kernels, weight matrices, bias values) of whatever artificial intelligence model is being trained (e.g., the machine learning model 402, the machine learning model 702) can be initialized in any suitable fashion (e.g., via random initialization).

In various embodiments, there can be a training image 1602 and a set of ground-truth localizations 1604. When it is desired to train the machine learning model 402, the training image 1602 can be any suitable training charged-particle microscopy image depicting any suitable specimen having any suitable number of instantiations of the structure of interest 306, and the set of ground-truth localizations 1604 can be whatever correct or accurate localizations (e.g., correct or accurate bounding boxes, correct or accurate segmentation masks) indicate or specify where non-defective instantiations of the structure of interest 306 are known or deemed to be located within the training image 1602. When it is desired to train the machine learning model 702, the training image 1602 can be any suitable training charged-particle microscopy image depicting any suitable specimen having any suitable number of instantiations of the structure of interest 306, and the set of ground-truth localizations 1604 can be whatever correct or accurate localizations (e.g., correct or accurate bounding boxes, correct or accurate segmentation masks) indicate or specify where all instantiations of the structure of interest 306, without regard to defect status, are known or deemed to be located within the training image 1602.

In any case, the artificial intelligence model that is being trained can be executed on the training image 1602, thereby causing that artificial intelligence model to produce an output 1606. For example, in some cases, the training image 1602 can be fed or routed to an input layer of the artificial intelligence model, the training image 1602 can complete a forward pass through one or more hidden layers of the artificial intelligence model, and an output layer of the artificial intelligence model can compute the output 1606 based on activation maps or feature maps provided by the one or more hidden layers of the artificial intelligence model.

Note that the format, size, or dimensionality of the output 1606 can be dictated by the number, arrangement, sizes, or other characteristics of the neurons, convolutional kernels, LSTM layers, or other internal parameters of the output layer (or of any other layers) of the artificial intelligence model. Accordingly, the output 1606 can be forced to have any desired format, size, or dimensionality, by adding, removing, or otherwise adjusting characteristics of the output layer (or of any other layers) of the artificial intelligence model.

In various aspects, if the output 1606 is produced by the machine learning model 402, the output 1606 can be considered as the predicted or inferred set of non-defective localizations that the machine learning model 402 believes should correspond to the training image 1602. If the output 1606 is produced by the machine learning model 702, the output 1606 can be considered as the predicted or inferred set of defect-agnostic localizations that the machine learning model 702 believes should correspond to the training image 1602. Note that, if the artificial intelligence model that is being trained has so far undergone no or little training, then the output 1606 can be highly inaccurate. In other words, the output 1606 can be very different from the set of ground-truth localizations 1604.

In various aspects, an error 1608 (e.g., mean absolute error, mean squared error, cross-entropy error) between the output 1606 and the set of ground-truth localizations 1604 can be computed. In various instances, the trainable internal parameters of the artificial intelligence model can be incrementally updated via backpropagation (e.g., stochastic gradient descent) based on the error 1608.

In various cases, such execution-and-update procedure can be repeated for any suitable number of training images. This can ultimately cause the trainable internal parameters of the artificial intelligence model (e.g., of the machine learning model 402, of the machine learning model 702) to become iteratively optimized for accurately performing its inferencing task (e.g., selective localization of non-defective instantiations for the machine learning model 402; defect-agnostic localization for the machine learning model 702). In various aspects, any suitable training batch sizes, any suitable error/loss functions, or any suitable training termination criteria can be utilized during such training.

Although the herein disclosure mainly describes the various artificial intelligence models as being trained in supervised fashion, this is a mere non-limiting example for ease of explanation and illustration. In various embodiments, any other suitable training paradigms can be used to train such artificial intelligence models, such as unsupervised training or reinforcement learning, any of which may be federated or non-federated.

The scientific instrument systems, methods, or techniques disclosed herein may include interactions with a human user (e.g., via a user local computing device 1920 discussed herein with reference to FIG. 19). These interactions may include providing information to the user (e.g., information regarding the operation of a scientific instrument such as the scientific instrument 1910 of FIG. 19, information regarding a sample being analyzed or other test or measurement performed by a scientific instrument, information retrieved from a local or remote database, or other information) or providing an option for a user to input commands (e.g., to control the operation of a scientific instrument such as the scientific instrument 1910 of FIG. 19, or to control the analysis of data generated by a scientific instrument), queries (e.g., to a local or remote database), or other information. In some embodiments, these interactions may be performed through a graphical user interface (GUI) that includes a visual display on a display device (e.g., a display device 1810 discussed herein with reference to FIG. 18) that provides outputs to the user and/or prompts the user to provide inputs (e.g., via one or more input devices, such as a keyboard, mouse, trackpad, or touchscreen, included in other I/O devices 1812 discussed herein with reference to FIG. 18). The scientific instrument systems, methods, or techniques disclosed herein may include any suitable GUIs for interaction with a user.

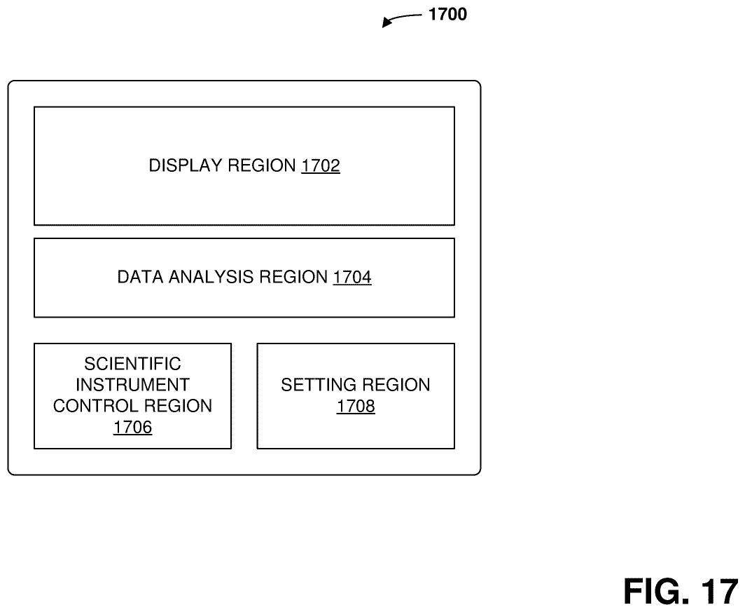

FIG. 17 depicts an example graphical user interface 1700 (hereafter “GUI 1700”) that can be used in the performance of some or all of the support methods or techniques disclosed herein, in accordance with various embodiments. In various aspects, the GUI 1700 can be provided on any suitable electronic display (e.g., a display device 1810 discussed herein with reference to FIG. 18) of a computing device (e.g., a computing device 1800 discussed herein with reference to FIG. 18) of a scientific instrument support system (e.g., a scientific instrument support system 1900 discussed herein with reference to FIG. 19), and a user or technician can interact with the GUI 1700 using any suitable input device (e.g., any of other I/O devices 1812 discussed herein with reference to FIG. 18) and input technique (e.g., movement of a cursor, motion capture, facial recognition, gesture detection, voice recognition, actuation of buttons).

The GUI 1700 can include a data display region 1702, a data analysis region 1704, a scientific instrument control region 1706, and a setting region 1708. The particular number and arrangement of regions depicted in FIG. 17 is merely illustrative, and any number and arrangement of regions, including any desired features, can be included in other embodiments of the GUI 1700.

The data display region 1702 can display data generated by a scientific instrument (e.g., a scientific instrument 1910 discussed herein with reference to FIG. 19).

The data analysis region 1704 can display any suitable data analysis results (e.g., the results of analyzing the data illustrated in the data display region 1702 or other data). In some embodiments, the data display region 1702 and the data analysis region 1704 can be combined in the GUI 1700 (e.g., to include both data output from a scientific instrument and some analysis of the data in a common graph or region).

The scientific instrument control region 1706 can include options that allow a user or technician to control a scientific instrument (e.g., the scientific instrument 1910 discussed herein with reference to FIG. 19). For example, the scientific instrument control region 1706 can include configurable parameters that govern operation of such scientific instrument (e.g., configurable parameters that govern voltages or electric currents of the scientific instrument, that govern interior temperatures of the scientific instrument, or that govern fluid flow rates of the scientific instrument).

The setting region 1708 can include options that allow a user or technician to control any features or functions of the GUI 1700 (or of other GUIs) or to perform common computing operations with respect to the data display region 1702 and the data analysis region 1704 (e.g., saving data on a storage device, such as the storage device 1804 discussed herein with reference to FIG. 18, sending data to another user, labeling data).

As noted above, the scientific instrument module 102 can be implemented by one or more computing devices. FIG. 18 is a block diagram of a computing device 1800 that can perform some or all of the scientific instrument methods or techniques disclosed herein, in accordance with various embodiments. In some embodiments, the scientific instrument module 102 can be implemented by a single instance of the computing device 1800 or by multiple instances of the computing device 1800. Further, as discussed below, the computing device 1800 (or multiple instances thereof) that implements the scientific instrument module 102 can be part of one or more of a scientific instrument 1910, a user local computing device 1920, a service local computing device 1930, or a remote computing device 1940 of FIG. 19.

The computing device 1800 is illustrated as having a number of components, but any one or more of these components can be omitted or duplicated, as suitable for the application and setting. In some embodiments, some or all of the components included in the computing device 1800 can be attached to one or more motherboards and enclosed in a housing (e.g., including plastic, metal, or other materials). In some embodiments, some these components can be fabricated onto a single system-on-a-chip (SoC) (e.g., an SoC may include one or more instances of a processing device 1802 and one or more instances of a storage device 1804). Additionally, in various embodiments, the computing device 1800 can omit one or more of the components illustrated in FIG. 18, but can include interface circuitry (not shown) for coupling to the one or more omitted components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 1800 can omit a display device 1810, but can include display device interface circuitry (e.g., a connector and driver circuitry) to which a display device 1810 can be coupled.

The computing device 1800 can include a processing device 1802 (e.g., one or more processing devices). As used herein, the term “processing device” can refer to any device or portion of a device that processes electronic data from registers or memory to transform that electronic data into other electronic data that may be stored in registers or memories. The processing device 1802 can include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 1800 can include a storage device 1804 (e.g., one or more storage devices). The storage device 1804 can include one or more memory devices such as random access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some embodiments, the storage device 1804 can include memory that shares a die with a processing device 1802. In such an embodiment, the memory may be used as cache memory and may include embedded dynamic random access memory (eDRAM) or spin transfer torque magnetic random access memory (STT-MRAM), for example. In some embodiments, the storage device 1804 can include non-transitory computer readable media having instructions thereon that, when executed by one or more processing devices (e.g., the processing device 1802), cause the computing device 1800 to perform any appropriate ones of or portions of the methods disclosed herein.

The computing device 1800 can include an interface device 1806 (e.g., one or more instances of the interface device 1806). The interface device 1806 can include one or more communication chips, connectors, or other hardware and software to govern communications between the computing device 1800 and other computing devices. For example, the interface device 1806 can include circuitry for managing wireless communications for the transfer of data to and from the computing device 1800. The term “wireless” and its derivatives may be used to describe circuits, devices, systems, methods, techniques, or communications channels that may communicate data through the use of modulated electromagnetic radiation through a nonsolid medium. The term does not imply that the associated devices do not contain any wires, although in some embodiments they might not. Circuitry included in the interface device 1806 for managing wireless communications may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”)). In some embodiments, circuitry included in the interface device 1806 for managing wireless communications can operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some embodiments, circuitry included in the interface device 1806 for managing wireless communications can operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some embodiments, circuitry included in the interface device 1806 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some embodiments, the interface device 1806 may include one or more antennas (e.g., one or more antenna arrays) to receipt and/or transmission of wireless communications.

In some embodiments, the interface device 1806 can include circuitry for managing wired communications, such as electrical, optical, or any other suitable communication protocols. For example, the interface device 1806 can include circuitry to support communications in accordance with Ethernet technologies. In some embodiments, the interface device 1806 can support both wireless and wired communication, or can support multiple wired communication protocols or multiple wireless communication protocols. For example, a first set of circuitry of the interface device 1806 may be dedicated to shorter-range wireless communications such as Wi-Fi or Bluetooth, and a second set of circuitry of the interface device 1806 may be dedicated to longer-range wireless communications such as global positioning system (GPS), EDGE, GPRS, CDMA, WiMAX, LTE, EV-DO, or others. In some embodiments, a first set of circuitry of the interface device 1806 can be dedicated to wireless communications, and a second set of circuitry of the interface device 1806 can be dedicated to wired communications.

The computing device 1800 can include battery/power circuitry 1808. The battery/power circuitry 1808 can include one or more energy storage devices (e.g., batteries or capacitors) or circuitry for coupling components of the computing device 1800 to an energy source separate from the computing device 1800 (e.g., alternating current line power).

The computing device 1800 can include a display device 1810 (e.g., multiple display devices). The display device 1810 can include any visual indicators, such as a heads-up display, a computer monitor, a projector, a touchscreen display, a liquid crystal display (LCD), a light-emitting diode display, or a flat panel display.

The computing device 1800 can include other input/output (I/O) devices 1812. The other I/O devices 1812 can include one or more audio output devices (e.g., speakers, headsets, earbuds, alarms), one or more audio input devices (e.g., microphones or microphone arrays), location devices (e.g., GPS devices in communication with a satellite-based system to receive a location of the computing device 1800), audio codecs, video codecs, printers, sensors (e.g., thermocouples or other temperature sensors, humidity sensors, pressure sensors, vibration sensors, accelerometers, gyroscopes), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 1800 can have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer), a desktop computing device, or a server computing device or other networked computing component.

One or more computing devices implementing any of the scientific instrument modules, methods, or techniques disclosed herein may be part of a scientific instrument support system. FIG. 19 is a block diagram of an example scientific instrument support system 1900 in which some or all of the scientific instrument support methods disclosed herein may be performed, in accordance with various embodiments. The scientific instrument modules, methods, or techniques disclosed herein (e.g., the scientific instrument module 102; the computer-implemented method 200; the system 309) can be implemented by one or more of a scientific instrument 1910, a user local computing device 1920, a service local computing device 1930, or a remote computing device 1940 of the scientific instrument support system 1900.

Any of the scientific instrument 1910, the user local computing device 1920, the service local computing device 1930, or the remote computing device 1940 can include any of the embodiments of the computing device 1800, and any of the scientific instrument 1910, the user local computing device 1920, the service local computing device 1930, or the remote computing device 1940 can take the form of any appropriate ones of the embodiments of the computing device 1800.

The scientific instrument 1910, the user local computing device 1920, the service local computing device 1930, or the remote computing device 1940 may each include a processing device 1902, a storage device 1904, and an interface device 1906. The processing device 1902 may take any suitable form, including any form of the processing device 1802, and the processing devices 1902 included in different ones of the scientific instrument 1910, the user local computing device 1920, the service local computing device 1930, or the remote computing device 1940 may take the same form or different forms. The storage device 1904 may take any suitable form, including any form of the storage device 1804, and the storage devices 1904 included in different ones of the scientific instrument 1910, the user local computing device 1920, the service local computing device 1930, or the remote computing device 1940 may take the same form or different forms. The interface device 1906 may take any suitable form, including any form of the interface device 1806, and the interface devices 1906 included in different ones of the scientific instrument 1910, the user local computing device 1920, the service local computing device 1930, or the remote computing device 1940 may take the same form or different forms.

The scientific instrument 1910, the user local computing device 1920, the service local computing device 1930, and the remote computing device 1940 can be in communication with other elements of the scientific instrument support system 1900 via communication pathways 1908. The communication pathways 1908 may communicatively couple the interface devices 1906 of different ones of the elements of the scientific instrument support system 1900, as shown, and may be wired or wireless communication pathways (e.g., in accordance with any of the communication techniques discussed herein with reference to the interface device 1806). The particular scientific instrument support system 1900 depicted in FIG. 19 includes communication pathways between each pair of the scientific instrument 1910, the user local computing device 1920, the service local computing device 1930, and the remote computing device 1940, but this “fully connected” implementation is merely illustrative, and in various embodiments, various ones of the communication pathways 1908 may be absent. For example, in some embodiments, a service local computing device 1930 can lack a direct communication pathway 1908 between its interface device 1906 and the interface device 1906 of the scientific instrument 1910, but can instead communicate with the scientific instrument 1910 via the communication pathway 1908 between the service local computing device 1930 and the user local computing device 1920 and the communication pathway 1908 between the user local computing device 1920 and the scientific instrument 1910.

The scientific instrument 1910 may include any appropriate scientific instrument, such as the charged-particle microscope 302.

The user local computing device 1920 can be a computing device (e.g., in accordance with any of the embodiments of the computing device 1800) that is local to a user of the scientific instrument 1910. In some embodiments, the user local computing device 1920 may also be local to the scientific instrument 1910, but this need not be the case; for example, a user local computing device 1920 that is in a user's home or office may be remote from, but in communication with, the scientific instrument 1910 so that the user may use the user local computing device 1920 to control or access data from the scientific instrument 1910. In some embodiments, the user local computing device 1920 may be a laptop, smartphone, or tablet device. In some embodiments the user local computing device 1920 can be a portable computing device.

The service local computing device 1930 can be a computing device (e.g., in accordance with any of the embodiments of the computing device 1800) that is local to an entity that services the scientific instrument 1910. For example, the service local computing device 1930 may be local to a manufacturer of the scientific instrument 1910 or to a third-party service company. In some embodiments, the service local computing device 1930 can communicate with the scientific instrument 1910, the user local computing device 1920, or the remote computing device 1940 (e.g., via a direct communication pathway 1908 or via multiple “indirect” communication pathways 1908, as discussed above) to receive data regarding the operation of the scientific instrument 1910, the user local computing device 1920, or the remote computing device 1940 (e.g., the results of self-tests of the scientific instrument 1910, calibration coefficients used by the scientific instrument 1910, the measurements of sensors associated with the scientific instrument 1910). In some embodiments, the service local computing device 1930 may communicate with the scientific instrument 1910, the user local computing device 1920, or the remote computing device 1940 (e.g., via a direct communication pathway 1908 or via multiple “indirect” communication pathways 1908, as discussed above) to transmit data to the scientific instrument 1910, the user local computing device 1920, or the remote computing device 1940 (e.g., to update programmed instructions, such as firmware, in the scientific instrument 1910, to initiate the performance of test or calibration sequences in the scientific instrument 1910, to update programmed instructions, such as software, in the user local computing device 1920 or the remote computing device 1940). A user of the scientific instrument 1910 can utilize the scientific instrument 1910 or the user local computing device 1920 to communicate with the service local computing device 1930 to report a problem with the scientific instrument 1910 or the user local computing device 1920, to request a visit from a technician to improve the operation of the scientific instrument 1910, to order consumables or replacement parts associated with the scientific instrument 1910, or for other purposes.

The remote computing device 1940 can be a computing device (e.g., in accordance with any of the embodiments of the computing device 1800 discussed herein) that is remote from the scientific instrument 1910 or from the user local computing device 1920. In some embodiments, the remote computing device 1940 can be included in a datacenter or other large-scale server environment. In some embodiments, the remote computing device 1940 may include network-attached storage (e.g., as part of the storage device 1904). The remote computing device 1940 can store data generated by the scientific instrument 1910, perform analyses of the data generated by the scientific instrument 1910 (e.g., in accordance with programmed instructions), facilitate communication between the user local computing device 1920 and the scientific instrument 1910, or facilitate communication between the service local computing device 1930 and the scientific instrument 1910.

In some embodiments, one or more of the elements of the scientific instrument support system 1900 illustrated in FIG. 19 can be omitted. Further, in some embodiments, multiple ones of various ones of the elements of the scientific instrument support system 1900 of FIG. 19 may be present. For example, a scientific instrument support system 1900 can include multiple user local computing devices 1920 (e.g., different user local computing devices 1920 associated with different users or in different locations). In another example, a scientific instrument support system 1900 may include multiple scientific instruments 1910, all in communication with service local computing device 1930 and/or a remote computing device 1940; in such an embodiment, the service local computing device 1930 may monitor these multiple scientific instruments 1910, and the service local computing device 1930 may cause updates or other information may be “broadcast” to multiple scientific instruments 1910 at the same time. Different ones of the scientific instruments 1910 in a scientific instrument support system 1900 can be located close to one another (e.g., in the same room) or farther from one another (e.g., on different floors of a building, in different buildings, in different cities, etc.). In some embodiments, a scientific instrument 1910 can be connected to an Internet-of-Things (IOT) stack that allows for command and control of the scientific instrument 1910 through a web-based application, a virtual or augmented reality application, a mobile application, or a desktop application. Any of these applications can be accessed by a user operating the user local computing device 1920 in communication with the scientific instrument 1910 by the intervening remote computing device 1940. In some embodiments, a scientific instrument 1910 may be sold by the manufacturer along with one or more associated user local computing devices 1920 as part of a local scientific instrument computing unit 1912.

In some embodiments, different ones of the scientific instruments 1910 included in a scientific instrument support system 1900 may be different types of scientific instruments 1910; for example, one scientific instrument 1910 may be a mass spectrometer, while another scientific instrument 1910 may be a chromatograph or autosampler. In some such embodiments, the remote computing device 1940 or the user local computing device 1920 can combine data from different types of scientific instruments 1910 included in a scientific instrument support system 1900.

In various instances, machine learning algorithms or models can be implemented in any suitable way to facilitate any suitable aspects described herein. To facilitate some of the above-described machine learning aspects of various embodiments, consider the following discussion of artificial intelligence (Al). Various embodiments described herein can employ artificial intelligence to facilitate automating one or more features or functionalities. The components can employ various Al-based schemes for carrying out various embodiments/examples disclosed herein. In order to provide for or aid in the numerous determinations (e.g., determine, ascertain, infer, calculate, predict, prognose, estimate, derive, forecast, detect, compute) described herein, components described herein can examine the entirety or a subset of the data to which it is granted access and can provide for reasoning about or determine states of the system or environment from a set of observations as captured via events or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events or data.

Such determinations can result in the construction of new events or actions from a set of observed events or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes or systems (e.g., support vector machines, neural networks, expert systems, Bayesian belief networks, fuzzy logic, data fusion engines, and so on) in connection with performing automatic or determined action in connection with the claimed subject matter. Thus, classification schemes or systems can be used to automatically learn and perform a number of functions, actions, or determinations.

A classifier can map an input attribute vector, z=(z₁, z₂, z₃, z₄, zₙ), to a confidence that the input belongs to a class, as by f(z)=confidence (class). Such classification can employ a probabilistic or statistical-based analysis (e.g., factoring into the analysis utilities and costs) to determinate an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, or probabilistic classification models providing different patterns of independence, any of which can be employed. Classification as used herein also is inclusive of statistical regression that is utilized to develop models of priority.

In order to provide additional context for various embodiments described herein, FIG. 20 and the following discussion are intended to provide a brief, general description of a suitable computing environment 2000 in which the various embodiments of the embodiment described herein can be implemented. While the embodiments have been described above in the general context of computer-executable instructions that can run on one or more computers, those skilled in the art will recognize that the embodiments can be also implemented in combination with other program modules or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multi-processor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 20, the example environment 2000 for implementing various embodiments of the aspects described herein includes a computer 2002, the computer 2002 including a processing unit 2004, a system memory 2006 and a system bus 2008. The system bus 2008 couples system components including, but not limited to, the system memory 2006 to the processing unit 2004. The processing unit 2004 can be any of various commercially available processors. Dual microprocessors and other multi-processor architectures can also be employed as the processing unit 2004.

The system bus 2008 can be any of several types of bus structure that can further interconnect to a memory bus (with or without a memory controller), a peripheral bus, and a local bus using any of a variety of commercially available bus architectures. The system memory 2006 includes ROM 2010 and RAM 2012. A basic input/output system (BIOS) can be stored in a non-volatile memory such as ROM, erasable programmable read only memory (EPROM), EEPROM, which BIOS contains the basic routines that help to transfer information between elements within the computer 2002, such as during startup. The RAM 2012 can also include a high-speed RAM such as static RAM for caching data.

The computer 2002 further includes an internal hard disk drive (HDD) 2014 (e.g., EIDE, SATA), one or more external storage devices 2016 (e.g., a magnetic floppy disk drive (FDD) 2016, a memory stick or flash drive reader, a memory card reader, etc.) and a drive 2020, e.g., such as a solid state drive, an optical disk drive, which can read or write from a disk 2022, such as a CD-ROM disc, a DVD, a BD, etc. Alternatively, where a solid state drive is involved, disk 2022 would not be included, unless separate. While the internal HDD 2014 is illustrated as located within the computer 2002, the internal HDD 2014 can also be configured for external use in a suitable chassis (not shown). Additionally, while not shown in environment 2000, a solid state drive (SSD) could be used in addition to, or in place of, an HDD 2014. The HDD 2014, external storage device(s) 2016 and drive 2020 can be connected to the system bus 2008 by an HDD interface 2024, an external storage interface 2026 and a drive interface 2028, respectively. The interface 2024 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 2002, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 2012, including an operating system 2030, one or more application programs 2032, other program modules 2034 and program data 2036. All or portions of the operating system, applications, modules, or data can also be cached in the RAM 2012. The systems and methods described herein can be implemented utilizing various commercially available operating systems or combinations of operating systems.

Computer 2002 can optionally comprise emulation technologies. For example, a hypervisor (not shown) or other intermediary can emulate a hardware environment for operating system 2030, and the emulated hardware can optionally be different from the hardware illustrated in FIG. 20. In such an embodiment, operating system 2030 can comprise one virtual machine (VM) of multiple VMs hosted at computer 2002. Furthermore, operating system 2030 can provide runtime environments, such as the Java runtime environment or the .NET framework, for applications 2032. Runtime environments are consistent execution environments that allow applications 2032 to run on any operating system that includes the runtime environment. Similarly, operating system 2030 can support containers, and applications 2032 can be in the form of containers, which are lightweight, standalone, executable packages of software that include, e.g., code, runtime, system tools, system libraries and settings for an application.

Further, computer 2002 can be enable with a security module, such as a trusted processing module (TPM). For instance with a TPM, boot components hash next in time boot components, and wait for a match of results to secured values, before loading a next boot component. This process can take place at any layer in the code execution stack of computer 2002, e.g., applied at the application execution level or at the operating system (OS) kernel level, thereby enabling security at any level of code execution.

A user can enter commands and information into the computer 2002 through one or more wired/wireless input devices, e.g., a keyboard 2038, a touch screen 2040, and a pointing device, such as a mouse 2042. Other input devices (not shown) can include a microphone, an infrared (IR) remote control, a radio frequency (RF) remote control, or other remote control, a joystick, a virtual reality controller or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 2004 through an input device interface 2044 that can be coupled to the system bus 2008, but can be connected by other interfaces, such as a parallel port, an IEEE 1394 serial port, a game port, a USB port, an IR interface, a BLUETOOTH® interface, etc.

A monitor 2046 or other type of display device can be also connected to the system bus 2008 via an interface, such as a video adapter 2048. In addition to the monitor 2046, a computer typically includes other peripheral output devices (not shown), such as speakers, printers, etc.

The computer 2002 can operate in a networked environment using logical connections via wired or wireless communications to one or more remote computers, such as a remote computer(s) 2050. The remote computer(s) 2050 can be a workstation, a server computer, a router, a personal computer, portable computer, microprocessor-based entertainment appliance, a peer device or other common network node, and typically includes many or all of the elements described relative to the computer 2002, although, for purposes of brevity, only a memory/storage device 2052 is illustrated. The logical connections depicted include wired/wireless connectivity to a local area network (LAN) 2054 or larger networks, e.g., a wide area network (WAN) 2056. Such LAN and WAN networking environments are commonplace in offices and companies, and facilitate enterprise-wide computer networks, such as intranets, all of which can connect to a global communications network, e.g., the Internet.

When used in a LAN networking environment, the computer 2002 can be connected to the local network 2054 through a wired or wireless communication network interface or adapter 2058. The adapter 2058 can facilitate wired or wireless communication to the LAN 2054, which can also include a wireless access point (AP) disposed thereon for communicating with the adapter 2058 in a wireless mode.

When used in a WAN networking environment, the computer 2002 can include a modem 2060 or can be connected to a communications server on the WAN 2056 via other means for establishing communications over the WAN 2056, such as by way of the Internet. The modem 2060, which can be internal or external and a wired or wireless device, can be connected to the system bus 2008 via the input device interface 2044. In a networked environment, program modules depicted relative to the computer 2002 or portions thereof, can be stored in the remote memory/storage device 2052. It will be appreciated that the network connections shown are example and other means of establishing a communications link between the computers can be used.

When used in either a LAN or WAN networking environment, the computer 2002 can access cloud storage systems or other network-based storage systems in addition to, or in place of, external storage devices 2016 as described above, such as but not limited to a network virtual machine providing one or more aspects of storage or processing of information. Generally, a connection between the computer 2002 and a cloud storage system can be established over a LAN 2054 or WAN 2056 e.g., by the adapter 2058 or modem 2060, respectively. Upon connecting the computer 2002 to an associated cloud storage system, the external storage interface 2026 can, with the aid of the adapter 2058 or modem 2060, manage storage provided by the cloud storage system as it would other types of external storage. For instance, the external storage interface 2026 can be configured to provide access to cloud storage sources as if those sources were physically connected to the computer 2002.

The computer 2002 can be operable to communicate with any wireless devices or entities operatively disposed in wireless communication, e.g., a printer, scanner, desktop or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

FIG. 21 is a schematic block diagram of a sample computing environment 2100 with which the disclosed subject matter can interact. The sample computing environment 2100 includes one or more client(s) 2110. The client(s) 2110 can be hardware or software (e.g., threads, processes, computing devices). The sample computing environment 2100 also includes one or more server(s) 2130. The server(s) 2130 can also be hardware or software (e.g., threads, processes, computing devices). The servers 2130 can house threads to perform transformations by employing one or more embodiments as described herein, for example. One possible communication between a client 2110 and a server 2130 can be in the form of a data packet adapted to be transmitted between two or more computer processes. The sample computing environment 2100 includes a communication framework 2150 that can be employed to facilitate communications between the client(s) 2110 and the server(s) 2130. The client(s) 2110 are operably connected to one or more client data store(s) 2120 that can be employed to store information local to the client(s) 2110. Similarly, the server(s) 2130 are operably connected to one or more server data store(s) 2140 that can be employed to store information local to the servers 2130.

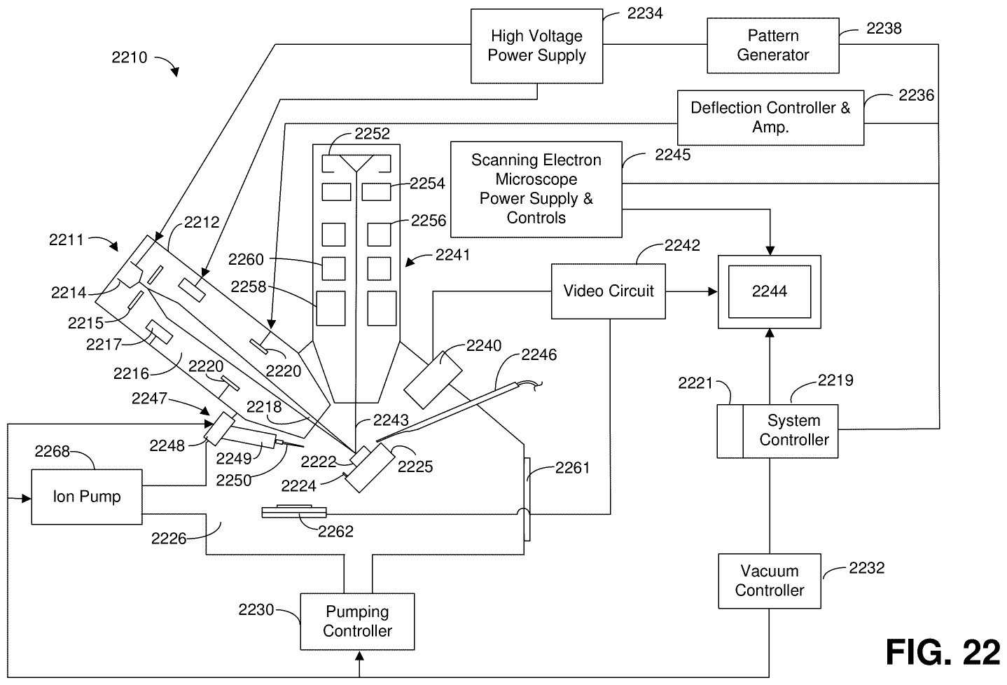

An example, non-limiting apparatus for performing various embodiments described herein is shown in FIG. 22. FIG. 22 illustrates a non-limiting example of a dual beam system 2210 with a vertically mounted scanning electron microscope (SEM) column and a focused ion beam (FIB) column mounted at an angle of approximately 52 degrees from the vertical. Such dual beam systems are commercially available, for example, from FEI Company, Hillsboro, Oregon, the assignee of the present application. While FIG. 22 shows an example of suitable microscopy hardware with which various embodiments described herein can be implemented, it is to be appreciated that such microscopy hardware is non-limiting. In other words, various embodiments described herein can be implemented in conjunction with any other suitable types of microscopy hardware. The dual beam system 2210 is a non-limiting example of the charged-particle microscope 302 or of any other scientific instruments discussed above.

A scanning electron microscope 2241, along with a power supply and control unit 2245, can be provided with the dual beam system 2210. An electron beam 2243 can be emitted from a cathode 2252 by applying voltage between the cathode 2252 and an anode 2254. The electron beam 2243 can be focused to a fine spot by means of a condensing lens 2256 and an objective lens 2258. The electron beam 2243 can be scanned two-dimensionally on any suitable specimen by means of a deflection coil 2260. Operation of the condensing lens 2256, the objective lens 2258, or the deflection coil 2260 can be controlled by the power supply and control unit 2245.

The electron beam 2243 can be focused onto a substrate 2222, which can be on a movable X-Y stage 2225 within a lower chamber 2226. When the electrons in the electron beam 2243 strike the substrate 2222, secondary electrons can be emitted. These secondary electrons can be detected by a secondary electron detector 2240 as discussed below. A scanning transmission electron microscopy (STEM) detector 2262, located beneath a STEM sample holder 2224 and the movable X-Y stage 2225, can collect electrons that are transmitted through the sample mounted on the STEM sample holder 2224 as discussed above.

The dual beam system 2210 can also include a focused ion beam (FIB) system 2211 which can comprise an evacuated chamber having an upper neck portion 2212 within which can be located an ion source 2214 and a focusing column 2216 including extractor electrodes and an electrostatic optical system (in some cases, the upper neck portion can also be referred to as an ion column 2212). The axis of the focusing column 2216 can be tilted 52 degrees (or any other suitable angular displacement) from the axis of the electron column. The ion column 2212 can include an ion source 2214, an extraction electrode 2215, a focusing element 2217, deflection elements 2220, and a focused ion beam 2218. The focused ion beam 2218 can pass from the ion source 2214 through the focusing column 2216 and between electrostatic deflection means schematically indicated at numeral 2220 toward the substrate 2222, which can comprise, for example, a semiconductor device positioned on the movable X-Y stage 2225 within the lower chamber 2226.

The movable X-Y stage 2225 can move in a horizontal plane (along X and Y axes) and vertically (along Z axis). The movable X-Y stage 2225 can tilt approximately sixty (60) degrees and rotate about the Z axis. In some embodiments, a separate STEM sample stage (not shown) can be used. Such a STEM sample stage can be moveable in the X, Y, and Z axes. A door 2261 can be opened for inserting the substrate 2222 onto the movable X-Y stage 2225 or also for servicing an internal gas supply reservoir, if one is used. The door 2261 can be interlocked so that it cannot be opened if the system is under vacuum.

An ion pump 2268 can be employed for evacuating the neck portion 2212. The chamber 2226 can be evacuated with a turbomolecular and mechanical pumping system 2230 under the control of a vacuum controller 2232. Such vacuum system can provide within the chamber 2226 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

A high voltage power supply 2234 can provide an appropriate acceleration voltage to electrodes in the focusing column 2216 for energizing and the focused ion beam 2218. When it strikes the substrate 2222, material can be sputtered (that is, physically ejected) from the sample. Alternatively, the focused ion beam 2218 can decompose a precursor gas to deposit a material.

The high voltage power supply 2234 can be connected to the ion source 2214 (which can be a liquid metal ion source) as well as to appropriate electrodes in the ion beam focusing column 2216 for forming an approximately 1 keV to 60 keV ion beam 2218 and directing the same toward a sample. A deflection controller and amplifier 2236, operated in accordance with a prescribed pattern provided by a pattern generator 2238, can be coupled to the deflection elements 2220 (which can be deflection plates) whereby the focused ion beam 2218 may be controlled manually or automatically to trace out a corresponding pattern on the upper surface of the substrate 2222. In some systems, the deflection elements 2220 can be placed before the final lens. Beam blanking electrodes (not shown) within the ion beam focusing column 2216 can cause the focused ion beam 2218 to impact onto a blanking aperture (not shown) instead of the substrate 2222 when a blanking controller (not shown) applies a blanking voltage to a blanking electrode.

The ion source 2214 can provide a metal ion beam of gallium, for example. In other examples, the ion source 2214 may be a plasma ion source that extracts ions from a generated plasma. The source can be capable of being focused into a sub one-tenth micrometer wide beam at the substrate 2222 for either modifying the substrate 2222 by ion milling, enhanced etch, material deposition, or for the purpose of imaging the substrate 2222.

A charged particle detector 2240, such as an Everhart Thornley or multi-channel plate, used for detecting secondary ion or electron emission can be connected to a video circuit 2242 that can supply drive signals to a video monitor 2244 and receive deflection signals from a system controller 2219. The location of the charged particle detector 2240 within the lower chamber 2226 can vary in different embodiments. For example, the charged particle detector 2240 can be coaxial with the ion beam and include a hole for allowing the ion beam to pass. In other embodiments, secondary particles can be collected through a final lens and then diverted off axis for collection.

A micromanipulator 2247 can precisely move objects within the vacuum chamber. The micromanipulator 2247 may comprise precision electric motors 2248 positioned outside the vacuum chamber to provide X, Y, Z, and theta control of a portion 2249 positioned within the vacuum chamber. The micromanipulator 2247 can be fitted with different end effectors for manipulating small objects. In various embodiments described herein, the end effector can be a thin probe 2250.

A gas delivery system 2246 can extend into the lower chamber 2226 for introducing and directing a gaseous vapor toward the substrate 2222. U.S. Pat. No. 5,851,413 to Casella et al. for “Gas Delivery Systems for Particle Beam Processing,” assigned to the assignee of the present invention, describes a suitable gas delivery system 2246. Another gas delivery system is described in U.S. Pat. No. 5,435,850 to Rasmussen for a “Gas Injection System,” also assigned to the assignee of the present invention. For example, iodine can be delivered to enhance etching, or a metal organic compound can be delivered to deposit a metal.

The system controller 2219 can control the operations of the various parts of the dual beam system 2210. Through the system controller 2219, a user can cause the focused ion beam 2218 or the electron beam 2243 to be scanned in a desired manner through commands entered into any suitable user interface (not shown). Alternatively, the system controller 2219 may control the dual beam system 2210 in accordance with programmed instructions stored in a memory 2221. In various embodiments, any of the one or more software components 313 can be implemented in or otherwise executed by the system controller 2219.

Various embodiments may be a system, a method, an apparatus or a computer program product at any possible technical detail level of integration. The computer program product can include a computer readable storage medium (or media) having computer readable program instructions thereon for causing a processor to carry out aspects of various embodiments. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network or a wireless network. The network can comprise copper transmission cables, optical transmission fibers, wireless transmission, routers, firewalls, switches, gateway computers or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of various embodiments can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform various aspects.

Various aspects are described herein with reference to flowchart illustrations or block diagrams of methods, apparatus (systems), and computer program products according to various embodiments. It will be understood that each block of the flowchart illustrations or block diagrams, and combinations of blocks in the flowchart illustrations or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart or block diagram block or blocks. These computer readable program instructions can also be stored in a computer readable storage medium that can direct a computer, a programmable data processing apparatus, or other devices to function in a particular manner, such that the computer readable storage medium having instructions stored therein comprises an article of manufacture including instructions which implement aspects of the function/act specified in the flowchart or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart or block diagram block or blocks.

The flowcharts and block diagrams in the Figures illustrate the architecture, functionality, and operation of possible implementations of systems, methods, and computer program products according to various embodiments. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer or computers, those skilled in the art will recognize that this disclosure also can or can be implemented in combination with other program modules. Generally, program modules include routines, programs, components, data structures, etc. that perform particular tasks or implement particular abstract data types. Moreover, those skilled in the art will appreciate that various aspects can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, or a computer. By way of illustration, both an application running on a server and the server can be a component. One or more components can reside within a process or thread of execution and a component can be localized on one computer or distributed between two or more computers. In another example, respective components can execute from various computer readable media having various data structures stored thereon. The components can communicate via local or remote processes such as in accordance with a signal having one or more data packets (e.g., data from one component interacting with another component in a local system, distributed system, or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. As used herein, the term “and/or” is intended to have the same meaning as “or.” Moreover, articles “a” and “an” as used in the subject specification and annexed drawings should generally be construed to mean “one or more” unless specified otherwise or clear from context to be directed to a singular form. As used herein, the terms “example” or “exemplary” are utilized to mean serving as an example, instance, or illustration. For the avoidance of doubt, the subject matter disclosed herein is not limited by such examples. In addition, any aspect or design described herein as an “example” or “exemplary” is not necessarily to be construed as preferred or advantageous over other aspects or designs, nor is it meant to preclude equivalent exemplary structures and techniques known to those of ordinary skill in the art.

The herein disclosure describes non-limiting examples. For ease of description or explanation, various portions of the herein disclosure utilize the term “each,” “every,” or “all” when discussing various examples. Such usages of the term “each,” “every,” or “all” are non-limiting. In other words, when the herein disclosure provides a description that is applied to “each,” “every,” or “all” of some particular object or component, it should be understood that this is a non-limiting example, and it should be further understood that, in various other examples, it can be the case that such description applies to fewer than “each,” “every,” or “all” of that particular object or component.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various non-limiting aspects are described in the following examples.

EXAMPLE 1: A system can comprise: a processor that can execute computer-executable components stored in a non-transitory computer-readable memory, wherein the computer-executable components can comprise: an access component that can access an image captured by a charged-particle microscope, wherein the image depicts a specimen; and a subtraction component that can localize one or more defective instantiations of a structure of interest of the specimen, based on execution of a first machine learning model that is trained to localize non-defective versions of the structure of interest.

EXAMPLE 2: The system of any preceding example can be implemented, wherein the computer-executable components can comprise: a non-defect component that can execute the first machine learning model on the image, such that the first machine learning model can receive as input the image and produce as output a set of non-defective localizations that respectively correspond to a set of non-defective instantiations of the structure of interest depicted in the image.

EXAMPLE 3: The system of any preceding example can be implemented, wherein the set of non-defective localizations can be a set of bounding boxes or a set of segmentation masks that respectively circumscribe or cover the set of non-defective instantiations of the structure of interest.

EXAMPLE 4: The system of any preceding example can be implemented, wherein the computer-executable components can comprise: a defect-agnostic component that can access a set of defect-agnostic localizations that respectively correspond to instantiations of the structure of interest depicted in the image regardless of defect status, and wherein the subtraction component can localize the one or more defective instantiations of the structure of interest by subtracting the set of non-defective localizations from the set of defect-agnostic localizations.

EXAMPLE 5: The system of any preceding example can be implemented, wherein the defect-agnostic component can access the set of defect-agnostic localizations by: executing on the image a second machine learning model that is trained to localize versions of the structure of interest without regard to defect status, such that the second machine learning model can receive as input the image and produce as output the set of defect-agnostic localizations.

EXAMPLE 6: The system of any preceding example can be implemented, wherein the defect-agnostic component can access the set of defect-agnostic localizations by: reading an electronic design file associated with the specimen.

EXAMPLE 7: The system of any preceding example can be implemented, wherein the defect-agnostic component can access the set of defect-agnostic localizations by: accessing an example image associated with the specimen, wherein all versions of the structure of interest depicted in the example image are non-defective; and executing on the example image the first machine learning model, such that the first machine learning model can receive as input the example image and produce as output the set of defect-agnostic localizations.

EXAMPLE 8: The system of any preceding example can be implemented, wherein the charged-particle microscope can be a scanning or transmission electron microscope, and wherein the specimen can be a fabricated semiconductor device.

EXAMPLE 9: The system of any preceding example can be implemented, wherein the structure of interest can be a nanowire of the fabricated semiconductor device, a fin of the fabricated semiconductor device, a gate of the fabricated semiconductor device, a drain of the fabricated semiconductor device, or a transistor of the fabricated semiconductor device.

In various embodiments, any combination or combinations of examples 1-9 can be implemented.

EXAMPLE 10: A computer-implemented method can comprise: accessing, by a device operatively coupled to a processor, an image captured by a charged-particle microscope, wherein the image depicts a specimen; and localizing, by the device, one or more defective instantiations of a structure of interest of the specimen, based on executing on the image a first machine learning model that is trained to localize non-defective versions of the structure of interest.

EXAMPLE 11: The computer-implemented method of any preceding example can be implemented, wherein the first machine learning model can receive as input the image and produce as output a set of non-defective localizations that respectively correspond to a set of non-defective instantiations of the structure of interest depicted in the image.

EXAMPLE 12: The computer-implemented method of any preceding example can be implemented, wherein the set of non-defective localizations can be a set of bounding boxes or a set of segmentation masks that respectively circumscribe or cover the set of non-defective instantiations of the structure of interest.

EXAMPLE 13: The computer-implemented method of any preceding example can be implemented, further comprising: accessing, by the device, a set of defect-agnostic localizations that respectively correspond to instantiations of the structure of interest depicted in the image regardless of defect status; and subtracting, by the device, the set of non-defective localizations from the set of defect-agnostic localizations, thereby yielding the one or more defective instantiations of the structure of interest.

EXAMPLE 14: The computer-implemented method of any preceding example can be implemented, wherein the accessing the set of defect-agnostic localizations can comprise: executing, by the device, on the image a second machine learning model that is trained to localize versions of the structure of interest without regard to defect status, such that the second machine learning model can receive as input the image and produce as output the set of defect-agnostic localizations.

EXAMPLE 15: The computer-implemented method of any preceding example can be implemented, wherein the accessing the set of defect-agnostic localizations can comprise: reading, by the device, an electronic design file associated with the specimen.

EXAMPLE 16: The computer-implemented method of any preceding example can be implemented, wherein the accessing the set of defect-agnostic localizations can comprise: accessing, by the device, an example image associated with the specimen, wherein all versions of the structure of interest depicted in the example image are non-defective; and executing, by the device, on the example image the first machine learning model, such that the first machine learning model can receive as input the example image and produce as output the set of defect-agnostic localizations.

EXAMPLE 17: The computer-implemented method of any preceding example can be implemented, wherein the charged-particle microscope can be a scanning or transmission electron microscope, and wherein the specimen can be a fabricated semiconductor device.

EXAMPLE 18: The computer-implemented method of any preceding example can be implemented, wherein the structure of interest can be a nanowire of the fabricated semiconductor device, a fin of the fabricated semiconductor device, a gate of the fabricated semiconductor device, a drain of the fabricated semiconductor device, or a transistor of the fabricated semiconductor device.

In various embodiments, any combination or combinations of examples 10-18 can be implemented.

EXAMPLE 19: A computer program product for facilitating subtractive defect localization for charged-particle microscopy can comprise a non-transitory computer-readable memory having program instructions embodied therewith. In various aspects, the program instructions can be executable by a processor to cause the processor to: access a scanned image depicting a semiconductor device having a repeated structure of interest; execute a defect-selective localizer on the scanned image, thereby yielding a set of first localizations that respectively indicate where in the scanned image non-defective instantiations of the repeated structure of interest are located; execute a defect-agnostic localizer on the scanned image, thereby yielding a set of second localizations that respectively indicate where in the scanned image defective or non-defective instantiations of the repeated structure of interest are located; and subtract the set of first localizations from the set of second localizations, thereby yielding a set of third localizations that respectively indicate where in the scanned image defective instantiations of the repeated structure of interest are located.

EXAMPLE 20: The computer program product of any preceding example can be implemented, wherein the repeated structure of interest can be a nanowire, fin, gate, drain, or transistor of the semiconductor device.

In various embodiments, any combination or combinations of examples 19-20 can be implemented.

In various embodiments, any combination or combinations of examples 1-20 can be implemented.

What is claimed is:

1. A system, comprising:
a processor that executes computer-executable components stored in a non-transitory computer-readable memory, wherein the computer-executable components comprise:
an access component that accesses an image captured by a charged-particle microscope, wherein the image depicts a specimen; and
a subtraction component that localizes one or more defective instantiations of a structure of interest of the specimen, based on execution of a first machine learning model that is trained to localize non-defective versions of the structure of interest.

2. The system of claim 1, wherein the computer-executable components comprise:
a non-defect component that executes the first machine learning model on the image, such that the first machine learning model receives as input the image and produces as output a set of non-defective localizations that respectively correspond to a set of non-defective instantiations of the structure of interest depicted in the image.

3. The system of claim 2, wherein the set of non-defective localizations is a set of bounding boxes or a set of segmentation masks that respectively circumscribe or cover the set of non-defective instantiations of the structure of interest.

4. The system of claim 2, wherein the computer-executable components comprise:
a defect-agnostic component that accesses a set of defect-agnostic localizations that respectively correspond to instantiations of the structure of interest depicted in the image regardless of defect status, and wherein the subtraction component localizes the one or more defective instantiations of the structure of interest by subtracting the set of non-defective localizations from the set of defect-agnostic localizations.

5. The system of claim 4, wherein the defect-agnostic component accesses the set of defect-agnostic localizations by:
executing on the image a second machine learning model that is trained to localize versions of the structure of interest without regard to defect status, such that the second machine learning model receives as input the image and produces as output the set of defect-agnostic localizations.

6. The system of claim 4, wherein the defect-agnostic component accesses the set of defect-agnostic localizations by:
reading an electronic design file associated with the specimen.

7. The system of claim 4, wherein the defect-agnostic component accesses the set of defect-agnostic localizations by:
accessing an example image associated with the specimen, wherein all versions of the structure of interest depicted in the example image are non-defective; and
executing on the example image the first machine learning model, such that the first machine learning model receives as input the example image and produces as output the set of defect-agnostic localizations.

8. The system of claim 1, wherein the charged-particle microscope is a scanning or transmission electron microscope, and wherein the specimen is a fabricated semiconductor device.

9. The system of claim 8, wherein the structure of interest is a nanowire of the fabricated semiconductor device, a fin of the fabricated semiconductor device, a gate of the fabricated semiconductor device, a drain of the fabricated semiconductor device, or a transistor of the fabricated semiconductor device.

10. A computer-implemented method, comprising:
accessing, by a device operatively coupled to a processor, an image captured by a charged-particle microscope, wherein the image depicts a specimen; and
localizing, by the device, one or more defective instantiations of a structure of interest of the specimen, based on executing on the image a first machine learning model that is trained to localize non-defective versions of the structure of interest.

11. The computer-implemented method of claim 10, wherein the first machine learning model receives as input the image and produces as output a set of non-defective localizations that respectively correspond to a set of non-defective instantiations of the structure of interest depicted in the image.

12. The computer-implemented method of claim 11, wherein the set of non-defective localizations is a set of bounding boxes or a set of segmentation masks that respectively circumscribe or cover the set of non-defective instantiations of the structure of interest.

13. The computer-implemented method of claim 11, further comprising:
accessing, by the device, a set of defect-agnostic localizations that respectively correspond to instantiations of the structure of interest depicted in the image regardless of defect status; and
subtracting, by the device, the set of non-defective localizations from the set of defect-agnostic localizations, thereby yielding the one or more defective instantiations of the structure of interest.

14. The computer-implemented method of claim 13, wherein the accessing the set of defect-agnostic localizations comprises:
executing, by the device, on the image a second machine learning model that is trained to localize versions of the structure of interest without regard to defect status, such that the second machine learning model receives as input the image and produces as output the set of defect-agnostic localizations.

15. The computer-implemented method of claim 13, wherein the accessing the set of defect-agnostic localizations comprises:
reading, by the device, an electronic design file associated with the specimen.

16. The computer-implemented method of claim 13, wherein the accessing the set of defect-agnostic localizations comprises:
accessing, by the device, an example image associated with the specimen, wherein all versions of the structure of interest depicted in the example image are non-defective; and
executing, by the device, on the example image the first machine learning model, such that the first machine learning model receives as input the example image and produces as output the set of defect-agnostic localizations.

17. The computer-implemented method of claim 10, wherein the charged-particle microscope is a scanning or transmission electron microscope, and wherein the specimen is a fabricated semiconductor device.

18. The computer-implemented method of claim 17, wherein the structure of interest is a nanowire of the fabricated semiconductor device, a fin of the fabricated semiconductor device, a gate of the fabricated semiconductor device, a drain of the fabricated semiconductor device, or a transistor of the fabricated semiconductor device.

19. A computer program product for facilitating subtractive defect localization for charged-particle microscopy, the computer program product comprising a non-transitory computer-readable memory having program instructions embodied therewith, the program instructions executable by a processor to cause the processor to:
access a scanned image depicting a semiconductor device having a repeated structure of interest;
execute a defect-selective localizer on the scanned image, thereby yielding a set of first localizations that respectively indicate where in the scanned image non-defective instantiations of the repeated structure of interest are located;
execute a defect-agnostic localizer on the scanned image, thereby yielding a set of second localizations that respectively indicate where in the scanned image defective or non-defective instantiations of the repeated structure of interest are located; and
subtract the set of first localizations from the set of second localizations, thereby yielding a set of third localizations that respectively indicate where in the scanned image defective instantiations of the repeated structure of interest are located.

20. The computer program product of claim 19, wherein the repeated structure of interest is a nanowire, fin, gate, drain, or transistor of the semiconductor device.
